(19) United States
(12) Patent Application Publication
(10) Pub. No.: US 2011/0198577 A1
(43) Pub. Date: Aug. 18, 2011

(54) ORGANIC ELECTROLUMINESCENT ELEMENT AND DISPLAY DEVICE

(75) Inventors: Emiko Kambe, Kanagawa (JP); Shigeyuki Matsunami, Kanagawa (JP); Yasunori Kijima, Tokyo (JP)

(73) Assignee: SONY CORPORATION, Tokyo (JP)

(21) Appl. No.: 13/120,202

(22) PCT Filed: Oct. 2, 2009
(86) PCT No.: PCT/JP2009/067257

§ 371 Date: Mar. 22, 2011

(30) Foreign Application Priority Data
Oct. 6, 2008 (JP) 2008-259352

(51) Int. Cl. H01L 51/54

(52) U.S. Cl. 257/40; 257/E51.026

(57) ABSTRACT

An organic electroluminescent element having high light emission efficiency, high color purity, and a long light emission lifetime, and a display device using the same are provided. In an organic electroluminescent element 11 having red light emission characteristics in which an organic layer 14 including a light emitting layer 14c is held between an anode 13 and a cathode 15, the light emitting layer 14c contains a guest material having the red light emission characteristics and a host material of a polycyclic aromatic hydrocarbon compound with a mother skeleton having 4 to 7 ring members. An electron transport layer 14d containing a specific benzimidazole derivative is provided adjacent to the light emitting layer 14c.

### TECHNICAL FIELD

The present invention relates to an organic electroluminescent element and a display device, and particularly relates to an organic electroluminescent element emitting red light, and a display device using the same.

### BACKGROUND ART

In recent years, a display device using an organic electroluminescent element (a so-called organic EL element) has attracted attention as a light-weight and high-efficiency flat panel type display device.

The organic electroluminescent element configuring such a display device is, for example, provided on a transparent substrate of glass or the like, and is formed by stacking an anode of ITO (Indium Tin Oxide: transparent electrode), an organic layer, and a cathode in this order from the substrate side. The organic layer has a structure in which a hole injection layer, a hole transport layer and a light emitting layer with electron transport characteristics, and, further, an electron transport layer and an electron injecting layer are sequentially stacked in this order from the anode side. In the organic electroluminescent element constituted in this manner, an electron injected from the cathode and a hole injected from the anode are recombined in the light emitting layer, and light generated at the time of this recombination is extracted from the substrate side through the anode.

As the organic electroluminescent element, in addition to the organic electroluminescent element having such a structure, there is an organic electroluminescent element having a structure in which the cathode, the organic layer, and the anode are sequentially stacked in this order from the substrate side, and, further, a so-called top emission type in which an electrode (an upper electrode as the cathode or the anode) positioned on the upper side is formed of a transparent material so that the light is extracted from the upper electrode side which is on the opposite side to the substrate. In particular, in an active matrix type display device in which a thin film transistor (Thin Film Transistor: TFT) is provided on a substrate, a so-called top emission (Top Emission) structure in which the top emission type organic electroluminescent element is provided on the substrate formed with TFT is advantageous for improvement of an aperture ratio of a light emitting section.

By the way, when practical use of the organic EL display is considered, it is necessary to improve the light emission efficiency of the organic electroluminescent element, in addition to improve the light extraction by increasing an aperture of the organic electroluminescent element. Thus, various materials and layer structures improving the light emission efficiency have been studied.

For example, for a red light emitting element, as a new red light emitting material in substitution for a pyrane derivative represented by DCJTB which has been known from the past, a structure using a naphthacene derivative (including a rubrene derivatative) as a dopant material is proposed. Moreover, for the electron transport layer adjacent to the light emitting layer containing such a red light emitting material, a material having favorable electron transport characteristics such as Alq3 is used (for example, refer to Patent Documents 1 and 2 below).

### CITATION LIST

### Patent Documents

Patent Document 1: Patent Publication No. 2000-26334
Patent Document 2: Patent Publication No. 2003-55652

### SUMMARY OF THE INVENTION

By the way, when a full color display is performed in the display device as described above, the organic electroluminescent elements of respective colors emitting three primary colors (red, green, and blue) are aligned and used, or the organic electroluminescent elements emitting white light, and a color filter of the respective colors or a color conversion layer are combined and used. Among them, a structure using the organic electroluminescent elements emitting the respective colors is advantageous from a viewpoint of the light extraction efficiency of the emitted light.

However, in the light emission of the red light emitting element using the above-described naphthacene derivative (the rubrene derivatative), the current efficiency is approximately 6.7 cd/A, and the color of the emitted light is orange, rather than red.

Moreover, many hosts of the red light emitting layer strongly exhibit the hole transporting characteristics. Thus, even in the structure in which the electron transport layer constituted by using the above-described electron transport material such as Alq3 is provided adjacent to the light emitting layer, a recombination region of the hole and the electron is easily expanded in the electron transport layer over the light emitting layer. Thereby, reduction of the light emission efficiency is generated in the light emitting layer. Moreover, in the case where the light emission is generated by the recombination of the hole and the electron in the electron transport layer, the color purity of the emitted light is reduced. Further, in the case of an electron transport material easily deteriorated by excitation, when the electron transport material is excited by the recombination of the hole and the electron in the electron transport layer, reduction of the lifetime characteristics is caused.

In view of the foregoing issues, it is an object of the present invention to provide an organic electroluminescent element emitting red light, which has high light emission efficiency and high color purity, and has favorable lifetime characteristics, and a display device using the same.

An organic electroluminescent element according to the present invention is an organic electroluminescent element having red light emission characteristics, in which an organic layer including a light emitting layer is held between an anode and a cathode. This light emitting layer contains a guest material having red light emission characteristics and a host material of a polycyclic aromatic hydrocarbon compound with a mother skeleton having 4 to 7 ring members. Moreover, an electron transport layer containing a benzimidazole derivative represented by the following general formula (1) is provided adjacent to the light emitting layer.

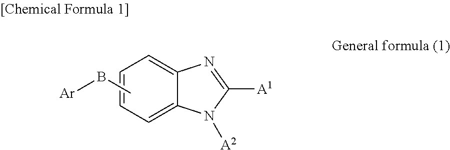

In the general formula (1), A¹ and A² each independently represent a hydrogen atom, a substituted or unsubstituted aryl group having 60 or less carbon atoms, a substituted or unsubstituted heterocyclic group, a substituted or unsubstituted alkyl group having 1 to 20 carbon atoms, or an alkoxy group having 1 to 20 carbon atoms.

In the general formula (1), B represents a paraphenylene group. This paraphenylene group is preferably bonded to a benzimidazole ring of the general formula (1) at a 5-position.

In the general formula (1), Ar represents an anthracene ring bonded to the paraphenylene group of B at a 2-position and a 6-position

In the organic electroluminescent element having such a structure, because a carrier recombination region is more concentrated in the light emitting layer compared with a carrier recombination region of an element using an electron transport material of the related art, current efficiency is increased and lifetime characteristics are improved as will be described in detail later in examples. Moreover, because the recombination region is not expanded to other layers, it is possible to obtain favorable highly-pure red light emission of only the light emission of the light emitting layer.

The display device according to the present invention is formed by aligning a plurality of the organic electroluminescent elements on a substrate.

In such a display device, as described above, because the organic electroluminescent element having high luminance and high color purity is used as a red light emitting element, it is possible to perform a full color display having high color reproducibility by combination of the red light emitting element, and other green light emitting element and other blue light emitting element.

As described above, according to the organic electroluminescent element of the present invention, it is possible to realize improvement of the light emission efficiency of the red light emission while the color purity is maintained, and, furthermore, it is possible to realize improvement of the lifetime characteristics.

Moreover, according to the display device of the present invention, as described above, a pixel is configured of a set of the organic electroluminescent element as being the red light emitting element having the high color purity and the high light emission efficiency, and a green light emitting element and a blue light emitting element, it is possible to perform the full color display having the high color reproducibility.

### BRIEF DESCRIPTION OF DRAWINGS

FIG. 1 is a cross-sectional view of an organic electroluminescent element according to an embodiment of the present invention.

FIG. 2 is a view illustrating an example of a circuit configuration of a display device.

FIG. 3 is a view illustrating an example of a cross-sectional structure of a main part in the display device.

FIG. 4 is a view illustrating the display device having a module shape to which the present invention is applied.

FIG. 5 is a perspective view illustrating a television device to which the present invention is applied.

FIG. 6 is a view illustrating a digital camera to which the present invention is applied, (A) is a perspective view as viewed from a front side, and (B) is a perspective view as viewed from a rear side.

FIG. 7 is a perspective view illustrating a notebook personal computer to which the present invention is applied.

FIG. 8 is a perspective view illustrating a video camera to which the present invention is applied.

FIG. 9 is a view illustrating a portable terminal device, for example, a portable phone, to which the present invention is applied, (A) is an elevation view in an unclosed state, (B) is a side view thereof, (C) is an elevation view in a closed state, (D) is a left side view, (E) is a right side face view, (F) is a top view, and (G) is a bottom view.

### DESCRIPTION OF EMBODIMENTS

Hereinafter, an embodiment of the present invention will be described in detail in order of an organic electroluminescent element and a display device using the same, based on drawings.

<<Organic Electroluminescent Element>>

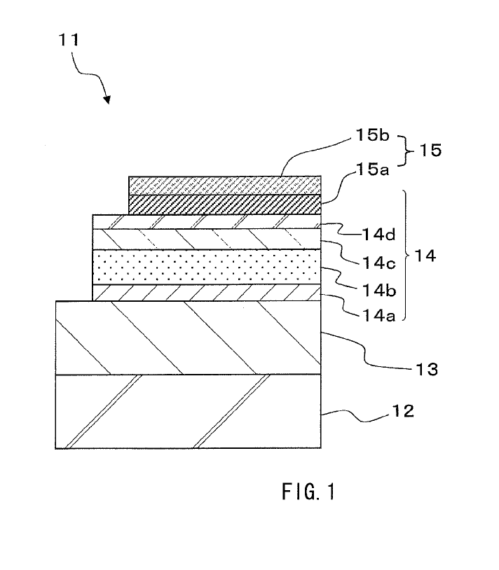

FIG. 1 is a cross-sectional view schematically illustrating an organic electroluminescent element according to an embodiment of the present invention. An organic electroluminescent element 11 is formed by stacking an anode 13, an organic layer 14, and a cathode 15 in this order on a substrate 12. Among them, the organic layer 14 is formed by stacking, for example, a hole injection layer 14a, a hole transport layer 14b, a light emitting layer 14c, and an electron transport layer 14d in this order from the anode 13 side.

This embodiment has characteristics in the structure of the light emitting layer 14c, and the structure of the electron transport layer 14d provided adjacent to the light emitting layer 14c. Hereinafter, the organic electroluminescent element 11 having such a stacked structure is constituted as a top emission type element in which light is extracted from the opposite side to the substrate 12, and details of each layer in this case will be sequentially described from the substrate 12 side.

<Substrate>

The substrate 12 is a support body on which the organic electroluminescent element 11 is aligned and formed on its main face side. The substrate 12 may be a known material, and, for example, quartz, glass, a metal foil, a resin film, a resin sheet, or the like is used. Among them, the quartz and the glass are preferable, and, in the case where the resin is used, a methacrylate resin represented by polymethyl methacrylate (PMMA), polyether such as polyethylene terephthalate (PET), polyethylene naphthalate (PEN), and polybutylene naphthalate (PBN), a polycarbonate resin, or the like is cited as a material, and a stacked structure suppressing the water permeability and the gas permeability, and performance of a surface treatment are necessary.

In the top emission structure of the top emission type in which the light is extracted from the opposite side to the substrate 12, it is not necessary for the substrate 12 itself to have the light transmittance, and, for example, a substrate formed of single crystal silicon may be used. Further, in the case where the display device configured by using the organic electroluminescent element 11 is an active drive type, a substrate in which active elements for driving the organic electroluminescent element 11 are formed is used.

<Anode>

For the anode 13, a material having a high work function from a vacuum level of an electrode material for efficiently injecting holes, for example, a metal such as aluminum (Al), chromium (Cr), molybdenum (Mo), tungsten (W), copper (Cu), silver (Ag), and gold (Au), an alloy of those, further, an oxide of these metals and the alloy, and the like, an alloy of tin oxide (SnO2) and antimony (Sb), ITO (indium tin oxide), InZnO (indium zinc oxide), an alloy of a zinc oxide (ZnO) and aluminum (Al), further, an oxide of these metals and these alloys, and the like are used as a single substance or are used in a mixed state.

The anode 13 may have a stacked structure of a first layer having excellent light reflectivity, and a second layer provided in an upper part of the first layer, having the light transmittance, and having a high work function.

Here, for the first layer, it is preferable to use an alloy mainly containing the aluminum as a main component. Its accessory component may contain at least one element having the work function relatively lower than that of the aluminum as being the main component. As such an accessory component, a lanthanoid element is preferable. Although the work function of the lanthanoid element is not high, stability of the anode is improved by containing these elements, and the hole injection characteristics of the anode are satisfied. Moreover, as the accessory component, elements such as silicon (Si) and copper (Cu) may be contained in addition to the lanthanoid element.

The content of the accessory component in an aluminum alloy layer constituting the first layer is, for example, preferably approximately 10 wt % or less in total, for example, if the accessory component is Nd, Ni, Ti or the like stabilizing the aluminum. Thereby, the aluminum alloy layer is stably maintained in a manufacture process of the organic electroluminescent element while the reflectivity in the aluminum alloy layer is maintained, and, further, it is possible to obtain process accuracy and chemical stability. Moreover, it is possible to improve conductivity of the anode 13, and adhesion between the anode 13 and the substrate 12.

As the second layer, a layer formed of at least one of an oxide of an aluminum alloy, an oxide of molybdenum, an oxide of zirconium, an oxide of chromium, and an oxide of tantalum can be exemplified. Here, for example, in the case where the second layer is an oxide layer (including a natural oxide film) of the aluminum alloy containing the lanthanoid element as the accessory component, because the transmittance of the oxide of the lanthanoid element is high, the transmittance of the second layer containing the lanthanoid element is favorable. Thus, it is possible to maintain high reflectivity on the surface of the first layer. Further, the second layer may be a transparent conductive layer of ITO (Indium Tin Oxide), IZO (Indium ZincOxide), or the like. It is possible for these conductive layers to improve the electron transport characteristics of the anode 13.

In the anode 13, a conductive layer to improve adhesion between the anode 13 and the substrate 12 may be provided on a side in contact with the substrate 12. As such a conductive layer, a transparent conductive layer of ITO, IZO, or the like is cited.

And, in the case where the drive method of the display device configured by using the organic electroluminescent element 11 is the active matrix method, the anode 13 is patterned for each pixel, and provided in the state of being connected to a thin film transistor for drive provided on the substrate 12. Moreover, in this case, an insulating film (not illustrated in the figure) is provided on the anode 13, and the anode 13 has a structure such that the surface of the anode 13 of each pixel is exposed from an aperture portion of this insulating film.

<Hole Injection Layer/Hole Transport Layer>

The hole injection layer 14a and the hole transport layer 14b improve the hole injection efficiency to the light emitting layer 14c, respectively. As materials of the hole injection layer 14a or the hole transport layer 14b, for example, benzene, styrylamine, triphenylamine, porphyrin, triphenylene, azatriphenylene, tetracyanoquinodimethane, triazole, imidazole, oxadiazole, polyarylalkane, phenylendiamine, arylamine, oxazole, anthracene, fluorenon, hydrazone, stilbene, a derivative of these, or a monomer, an oligomer, or a polymer of a heterocyclic conjugation type such as a polysilane compound, a vinylcarbazole compound, a thiophene compound, or a aniline compound can be used.

Further, as specific materials of the hole injection layer 14a or the hole transport layer 14b, α-naphthylphenylphenylenediamine, porphyrin, metal tetraphenylporphyrine, metal naphthalocyanine, hexacyanoazatriphenylene, 7,7,8,8-tetracyanoquinodimethane (TCNQ), 7,7,8,8-tetracyano-2,3,5,6-tetrafluoroquinodimethane (F4-TCNQ), tetracyano 4,4,4-tris (3-methylphenylphenylamino) triphenylamine, N,N,N′,N′-tetrakis (p-tolyl) p-phenylenediamine, N,N,N′,N′-tetraphenyl-4,4′-diaminephenyl, N-phenylcarbazole, 4-di-p-tolylaminostilbene, poly (paraphenylenevinylene), poly (thiophenevinylene), poly (2,2′-thienylpyrrole), or the like is cited, but they are not limited to these.

<Light Emitting Layer>

The light emitting layer 14c is a region in which the hole injected from the anode 13 side, and the electron injected from the cathode 15 side are recombined when a voltage is applied to the anode 13 and the cathode 15. The structure of the light emitting layer 14c is one of characteristics of this embodiment. That is, the light emitting layer 14c uses a polycyclic aromatic hydrocarbon compound with a mother skeleton having 4 to 7 ring members as a host material, the host material is doped with a guest material emitting red light, and the red emission light is generated.

Among them, the host material constituting the light emitting layer 14c is the polycyclic aromatic hydrocarbon compound with the mother skeleton having 4 to 7 ring members, and is selected from the polycyclic aromatic hydrocarbon compound with a pyrene skeleton, a benzopyrene skeleton, a chrysene skeleton, a naphthacene skeleton, a benzonaphthacene skeleton, a dibenzonaphthacene skeleton, a perylene skeleton, or a coronene skeleton.

Among them, it is preferable to use the naphthacene derivative represented by the following general formula (2) as the host material.

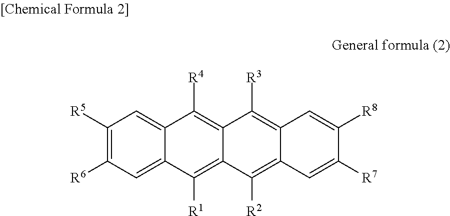

However, in the general formula (2), R¹ to R⁸ each independently represent hydrogen, halogen, a hydroxyl group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

As the aryl group represented by R¹ to R⁸ in the general formula (2), for example, a phenyl group, a 1-naphythyl group, a 2-naphythyl group, a fluorenyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 1-chrysenyl group, a 6-chrysenyl group, a 2-fluoranthenyl group, a 3-fluoranthenyl group, a 2-biphenylyl group, a 3-biphenylyl group, a 4-biphenylyl group, a o-tolyl group, an m-tolyl group, a p-tolyl group, a p-t-butylphenyl group, or the like is cited.

Moreover, as the heterocyclic group represented by R¹ to R⁸, a 5-membered or 6-membered aromatic heterocyclic group containing O, N, and S as a hetero atom, or a condensed polycyclic aromatic heterocyclic group having 2 to 20 carbon atoms is cited. Moreover, as the aromatic heterocyclic group and the condensed polycyclic aromatic heterocyclic group, a thienyl group, a furyl group, a pyrrolyl group, a pyridyl group, a quinolyl group, a quinoxalyl group, an imidazopyridyl group, or a benzothiazole group is cited. As representative examples, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 1-quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, or the like is cited.

The amino group represented by R¹ to R⁸ may be an alkylamino group, an arylamino group, an aralykylamino group, or the like. These preferably have an aliphatic group having a total of 1 to 6 carbon atoms and/or a monocyclic to tetracyclic aromatic carbon ring. As such a group, a dimethylamino group, a diethylamino group, a dibutylamino group, a diphenylamino group, a ditolylamino group, a bisbiphenylylamino group, or a dinaphthylamino group is cited.

In addition, two or more kinds of the above-described substituents may form a condensed ring, and may further have a substituent.

In particular, the naphthacene derivative represented by the above-described general formula (2) is preferably a rubrene derivative represented by the following general formula (2a).

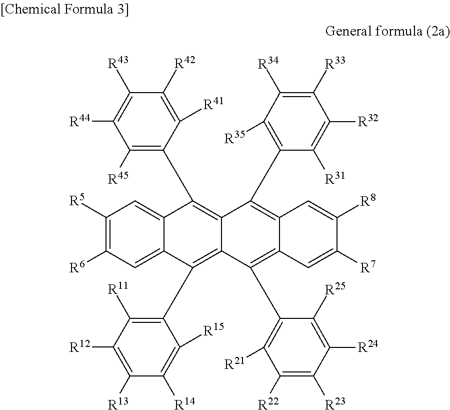

In the general formula (2a), R¹¹ to R¹⁵, R²¹ to R²⁵, R³¹ to R³⁵, and R⁴¹ to R⁴⁵ are each independently a hydrogen atom, an aryl group, a heterocyclic group, an amino group, an aryloxy group, an alkyl group, or an alkenyl group. However, R¹¹ to R¹⁵, R²¹, to R²⁵, R³¹ to R³⁵, and R⁴¹ to R⁴⁵ are each preferably the same.

R⁵ to R⁸ in the general formula (2a) are each independently a hydrogen atom, an aryl group which may have a substituent, an alkyl group which may have a substituent, or an alkenyl group which may have a substituent.

Preferred embodiments of the aryl group, the heterocyclic group, and the amino group in the general formula (2a) may be the same as R¹ to R⁸ in the general formula (2). In addition, in the case where R¹¹ to R¹⁵, R²¹ to R²⁵, R³¹ to R³⁵, and R⁴¹ to R⁴⁵ are the amino group, it is an alkylamino group, an arylamino group, or an aralkylamino group. These preferably have an aliphatic group having a total of 1 to 6 carbon atoms, or a monocyclic to tetracyclic aromatic carbon ring. As such a group, a dimethylamino group, a diethylamino group, a dibutylamino group, a diphenylamino group, a ditolylamino group, or a bisbiphenylylamino group is cited.

As other more specific examples of the naphthacene derivative suitably used as the host material of the light emitting layer 14c, rubrene of the following compound (2)-1 as being one of the rubrene derivatives of the general formula (2a) is cited, and, in addition to this, the following compounds (2)-2 to (2)-4 are exemplified.

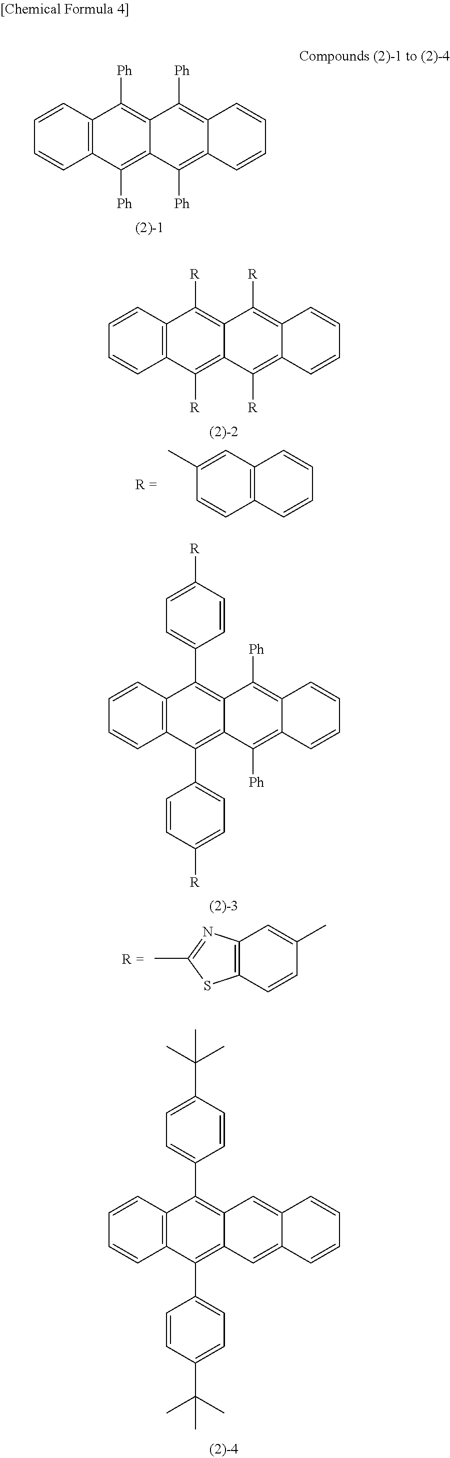

Moreover, as a red light emitting guest material constituting the light emitting layer 14c, a perylene derivative of the general formula (3), a diketopyrrolopyrrole derivative of the general formula (4), a pyrromethene complex of the general formula (5), a pyrane derivative of the general formula (6), or a styryl derivative of the general formula (7) which will be described next is used. Hereinafter, the red light emitting guest material will be described in detail.

—Perylene Derivative—

As the red light emitting guest material, for example, a compound (a dindeno[1,2,3-cd] perylene derivative) represented by the following general formula (3) is used.

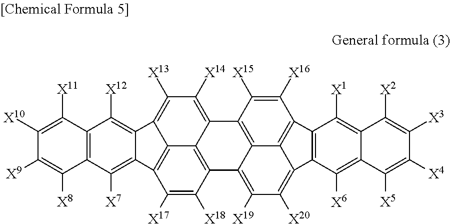

However, in the general formula (3), X¹ to X²⁰ each independently represent hydrogen, halogen, a hydroxyl group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

As the aryl group represented by X¹ to X²⁰ in the general formula (3), for example, a phenyl group, a 1-naphthyl group, a 2-naphthyl group, a fluorenyl group, a 1-anthryl group, a 2-anthryl group, a 9-anthryl group, a 1-phenanthryl group, a 2-phenanthryl group, a 3-phenanthryl group, a 4-phenanthryl group, a 9-phenanthryl group, a 1-naphthacenyl group, a 2-naphthacenyl group, a 9-naphthacenyl group, a 1-pyrenyl group, a 2-pyrenyl group, a 4-pyrenyl group, a 1-chrysenyl group, a 6-chrysenyl group, a 2-fluoranthenyl group, a 3-fluoranthenyl group, a 2-biphenylyl group, a 3-biphenylyl group, a 4-biphenylyl group, a o-tolyl group, an m-tolyl group, a p-tolyl group, a p-t-butylphenyl group, or the like is cited.

As the heterocyclic group represented by X¹ to X²⁰, a 5-membered or 6-membered aromatic heterocyclic group containing O, N, and S as a hetero atom, or a condensed polycyclic aromatic heterocyclic group having 2 to 20 carbon atoms is cited. As the aromatic heterocyclic group and the condensed polycyclic aromatic heterocyclic group, a thienyl group, a furyl group, a pyrrolyl group, a pyridyl group, a quinolyl group, a quinoxalyl group, an imidazopyridyl group, or a benzothiazole group is cited. As representative examples, a 1-pyrrolyl group, a 2-pyrrolyl group, a 3-pyrrolyl group, a pyrazinyl group, a 2-pyridinyl group, a 3-pyridinyl group, a 4-pyridinyl group, a 1-indolyl group, a 2-indolyl group, a 3-indolyl group, a 4-indolyl group, a 5-indolyl group, a 6-indolyl group, a 7-indolyl group, a 1-isoindolyl group, a 2-isoindolyl group, a 3-isoindolyl group, a 4-isoindolyl group, a 5-isoindolyl group, a 6-isoindolyl group, a 7-isoindolyl group, a 2-furyl group, a 3-furyl group, a 2-benzofuranyl group, a 3-benzofuranyl group, a 4-benzofuranyl group, a 5-benzofuranyl group, a 6-benzofuranyl group, a 7-benzofuranyl group, a 1-isobenzofuranyl group, a 3-isobenzofuranyl group, a 4-isobenzofuranyl group, a 5-isobenzofuranyl group, a 6-isobenzofuranyl group, a 7-isobenzofuranyl group, a 1-quinolyl group, a 3-quinolyl group, a 4-quinolyl group, a 5-quinolyl group, a 6-quinolyl group, a 7-quinolyl group, a 8-quinolyl group, a 1-isoquinolyl group, a 3-isoquinolyl group, a 4-isoquinolyl group, a 5-isoquinolyl group, a 6-isoquinolyl group, a 7-isoquinolyl group, a 8-isoquinolyl group, a 2-quinoxalinyl group, a 5-quinoxalinyl group, a 6-quinoxalinyl group, a 1-carbazolyl group, a 2-carbazolyl group, a 3-carbazolyl group, a 4-carbazolyl group, a 9-carbazolyl group, a 1-phenanthridinyl group, a 2-phenanthridinyl group, a 3-phenanthridinyl group, a 4-phenanthridinyl group, a 6-phenanthridinyl group, a 7-phenanthridinyl group, a 8-phenanthridinyl group, a 9-phenanthridinyl group, a 10-phenanthridinyl group, a 1-acridinyl group, a 2-acridinyl group, a 3-acridinyl group, a 4-acridinyl group, a 9-acridinyl group, or the like is cited.

The amino group represented by X¹ to X²⁰ may be an alkylamino group, an arylamino group, an aralykylamino group, or the like. These preferably have an aliphatic group having a total of 1 to 6 carbon atoms and/or a monocyclic to tetracyclic aromatic carbon ring. As such a group, a dimethylamino group, a diethylamino group, a dibutylamino group, a diphenylamino group, a ditolylamino group, a bisbiphenylylamino group, or a dinaphthylamino group is cited.

Two or more kinds of the above-described substituents may form a condensed ring, and may further have a substituent.

As specific examples of the dindeno [1,2,3-cd] perylene derivative suitably used as the red light emitting guest material in the light emitting layer 14c, the following compounds (3)-1 to (3)-8 are exemplified. However, the present invention is not limited to these in any way.

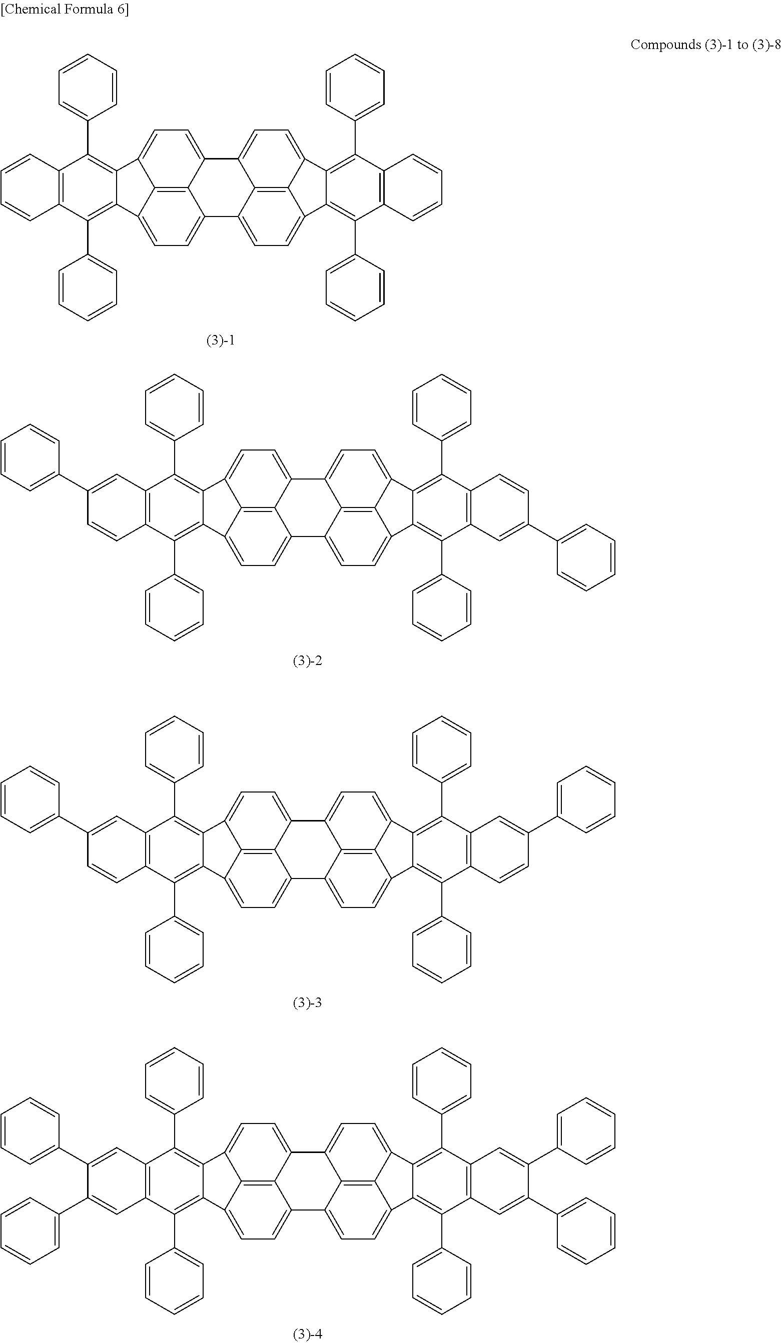

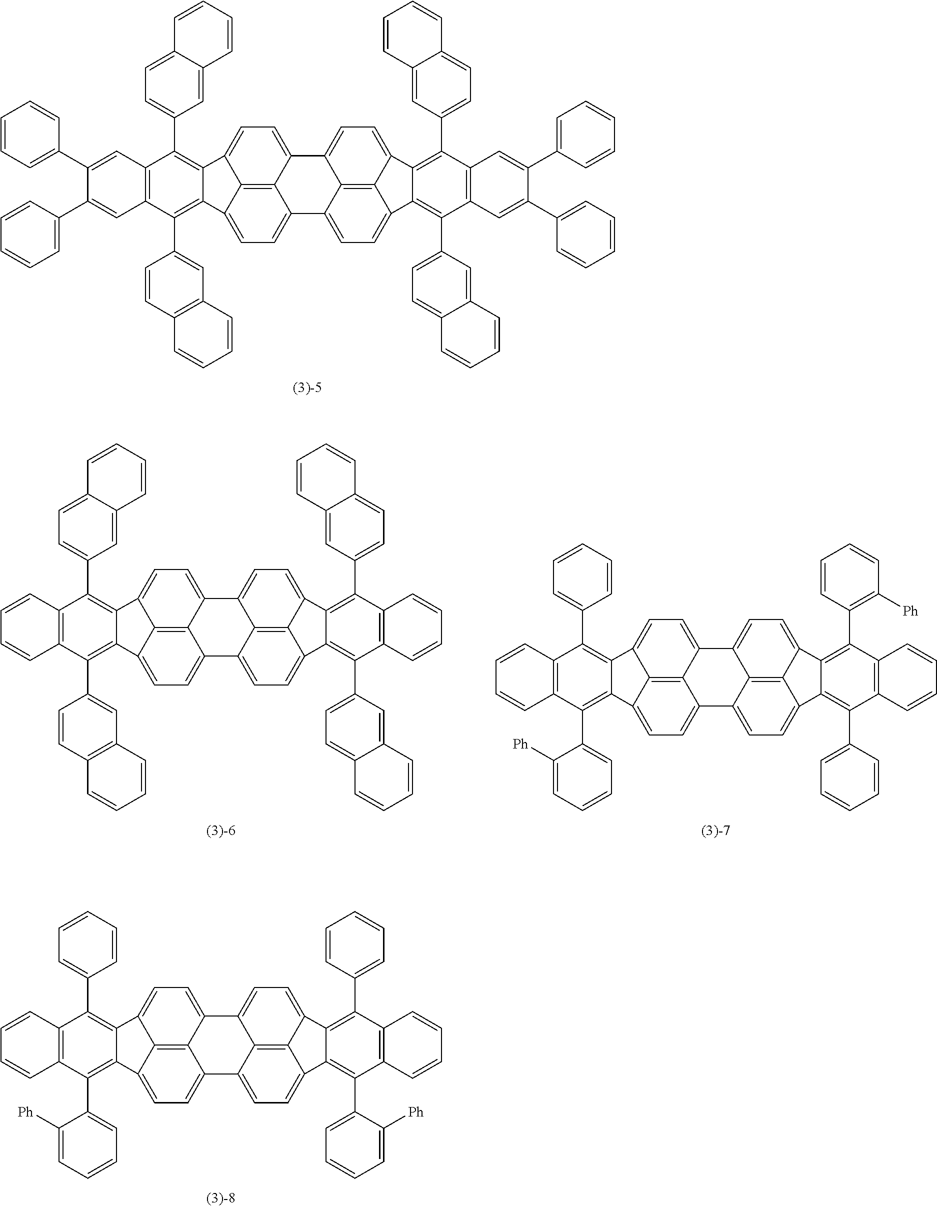

—Diketopyrrolopyrrole Derivative—

As the red light emitting guest material, for example, a compound (a diketopyrrolopyrrole derivative) represented by the following general formula (4) is used.

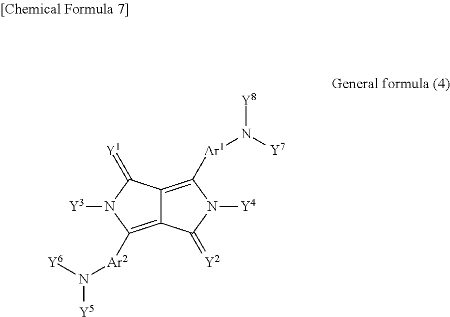

However, in the general formula (4), Y¹ and Y² each independently represent an oxygen atom, or a substituted or unsubstituted imino group. Moreover, Y³ to Y⁸ each independently represent hydrogen, halogen, a substituted or unsubstituted alkyl group having 20 or less carbon atoms, a substituted or unsubstituted alkenyl group having 20 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

In the general formula (4), Ar¹ and Ar² represent a divalent group selected from a substituted or unsubstituted aromatic hydrocarbon group, and a substituted or unsubstituted aromatic heterocyclic group.

In the general formula (4), the substituted or unsubstituted aryl group represented by Y³ to Y⁸, the heterocyclic group represented by Y³ to Y⁸, and, further, the amino group represented by Y³ to Y⁸ are the same as the group represented by the perylene derivative of the general formula (3). Moreover, two or more kinds of the above-described substituents may form a condensed ring, and may further have a substituent.

As specific examples of the diketopyrrolopyrrole derivative suitably used as the red light emitting guest material in the light emitting layer 14c, the following compounds (4)-1 to (4)-14 are exemplified. However, the present invention is not limited to these in any way.

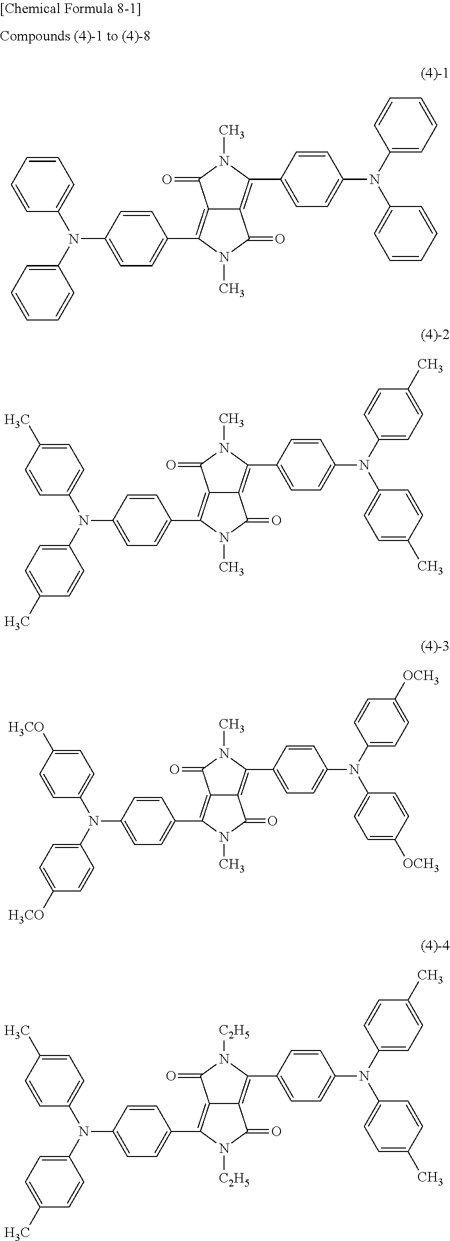

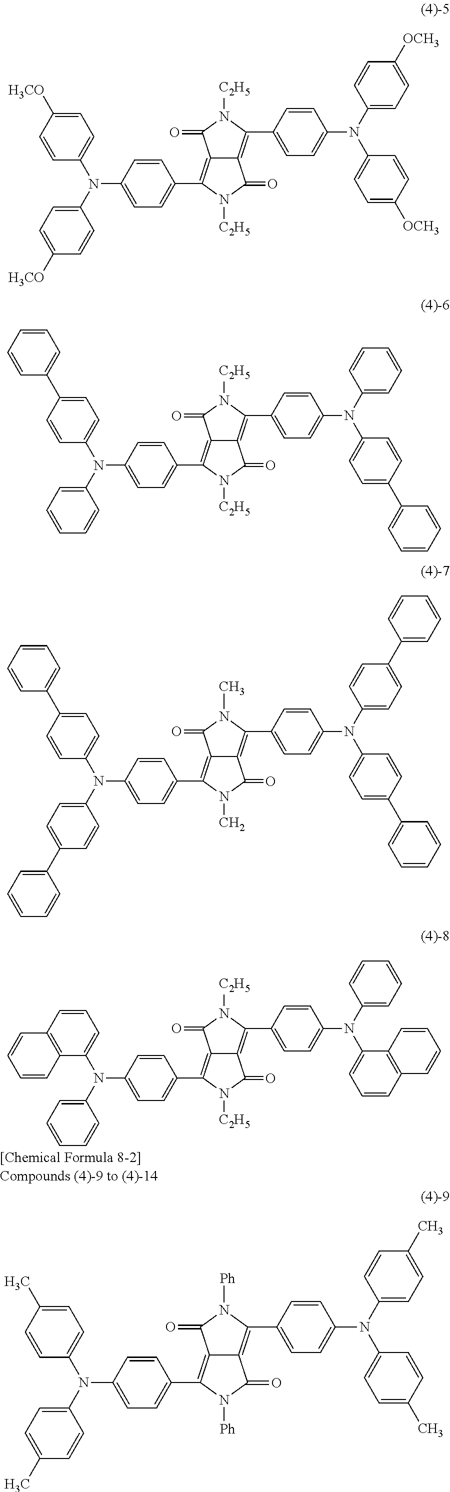

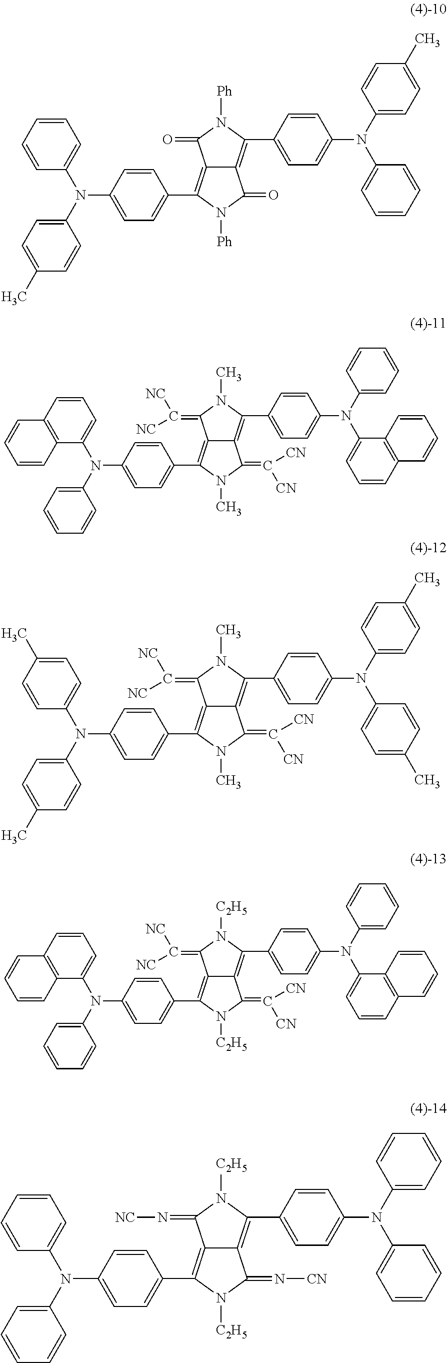

—Pyrromethene Complex—

As the red light emitting guest material, for example, a compound (a pyrromethene complex) represented by the following general formula (5) is used.

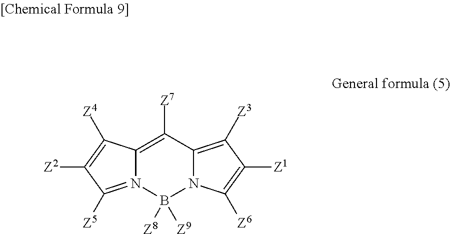

However, in the general formula (5), Z¹ to Z⁹ each independently represent hydrogen, halogen, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

In the general formula (5), the substituted or unsubstituted aryl group represented by Z¹ to Z⁹, the heterocyclic group represented by Z¹ to Z⁹, and, the amino group represented by Z¹ to Z⁹ are the same as the group represented by the perylene derivative of the general formula (3). Moreover, two or more kinds of the above-described substituents may form a condensed ring, and may further have a substituent.

As specific examples of the pyrromethene complex suitably used as the red light emitting guest material in the light emitting layer 14c, the following compounds (5)-1 to (5)-68 are exemplified. However, the present invention is not limited to these in any way.

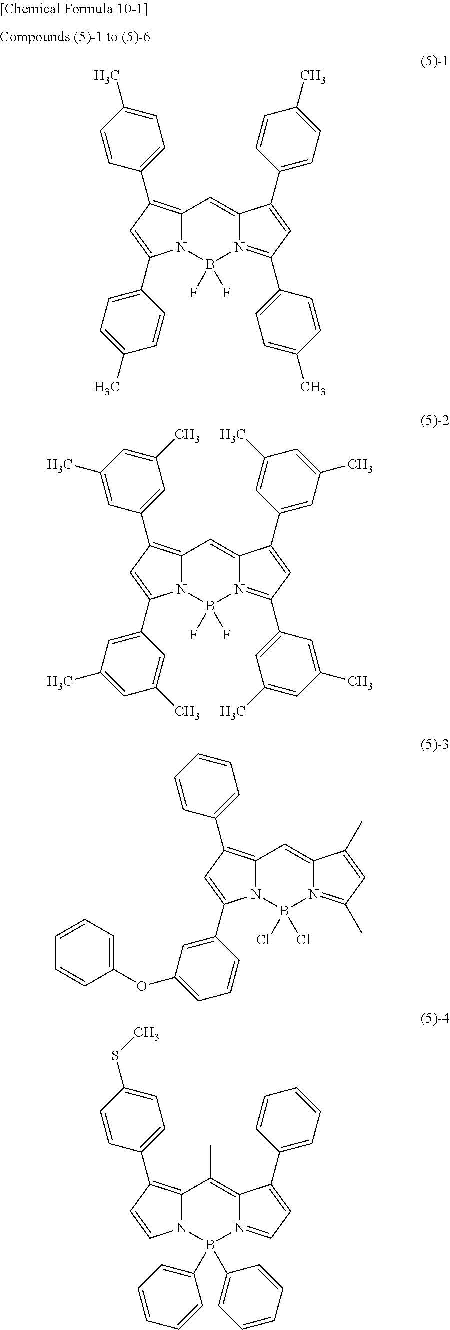

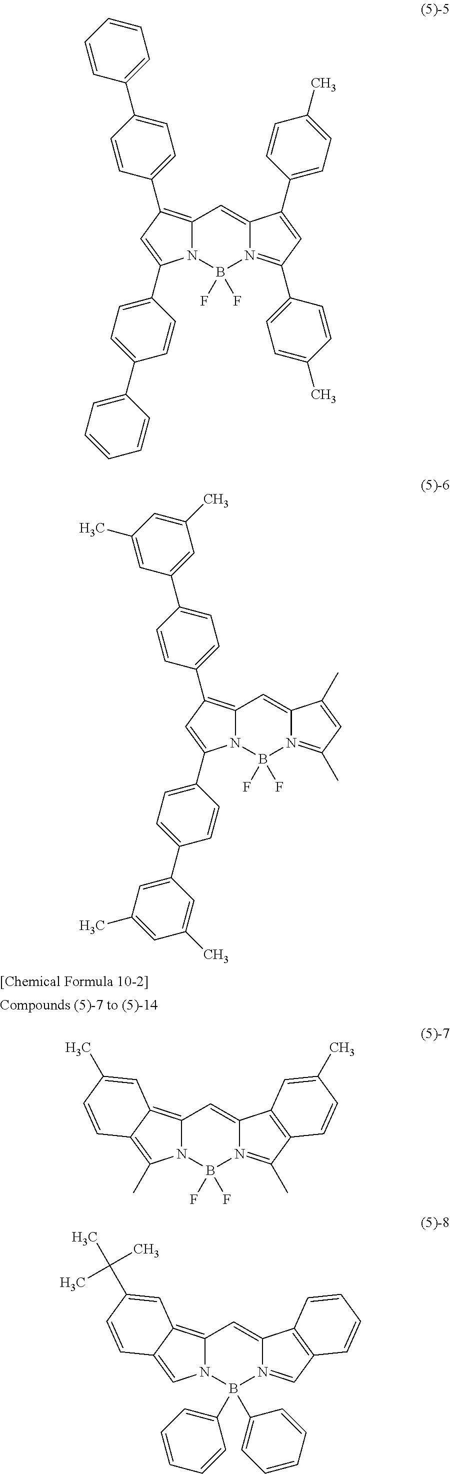

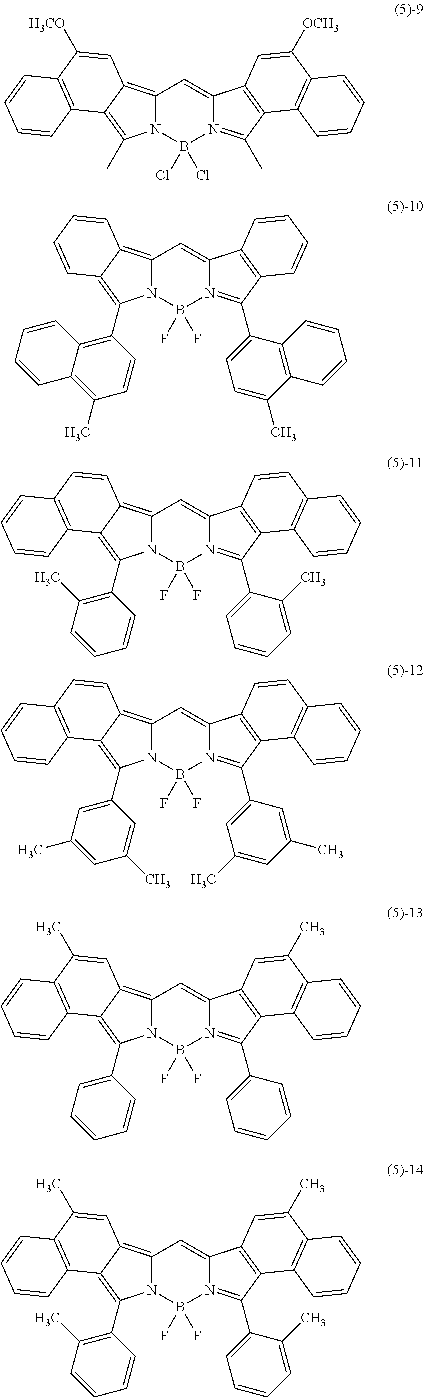

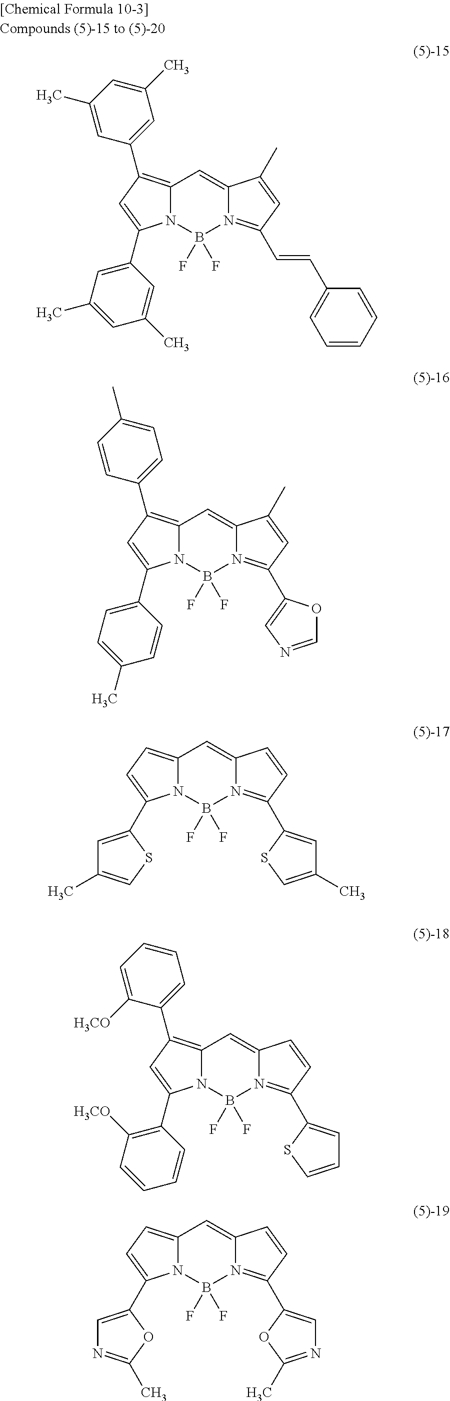

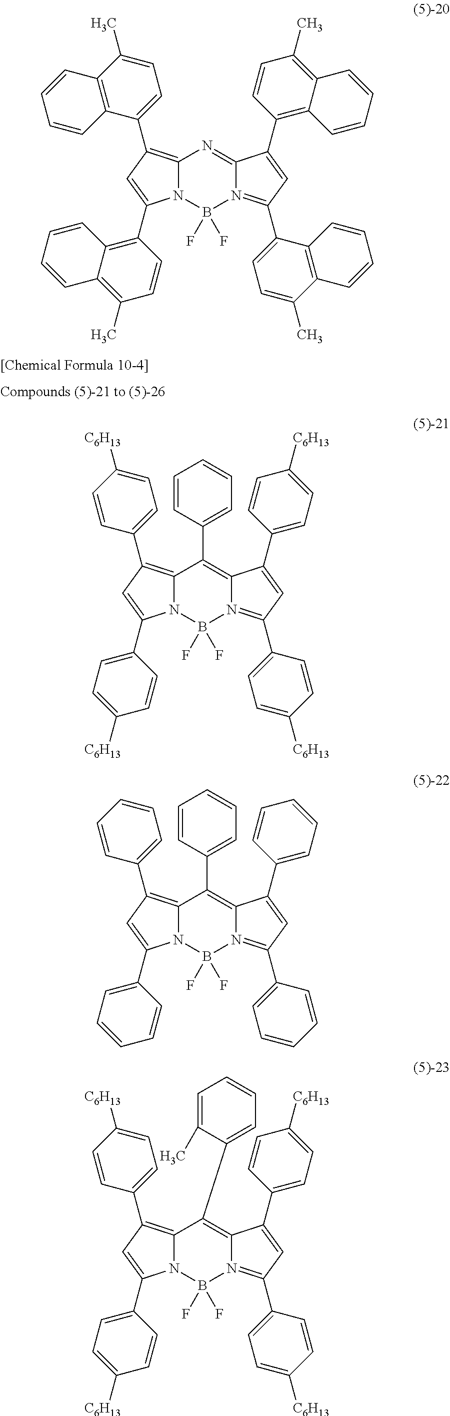

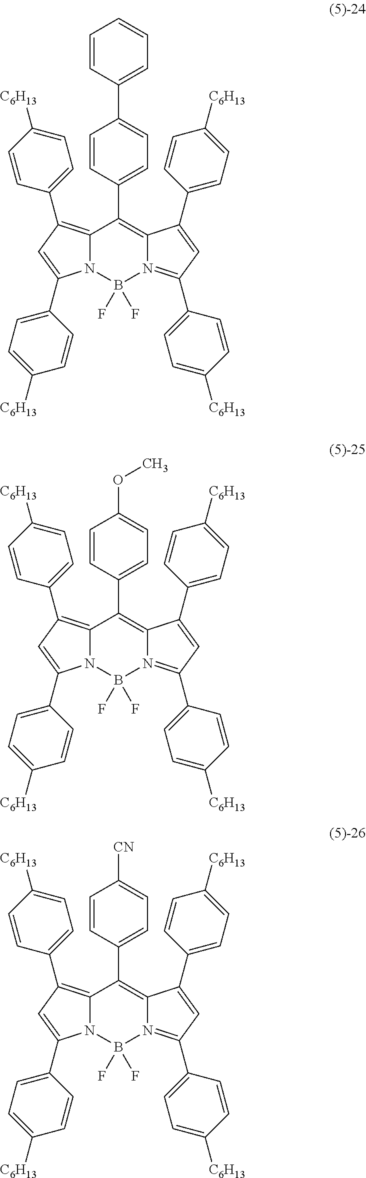

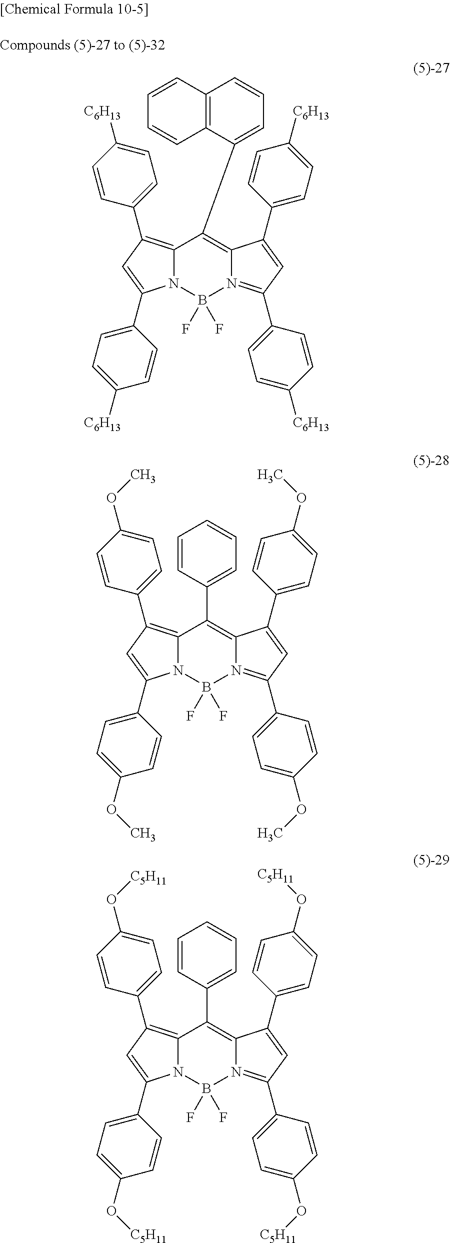

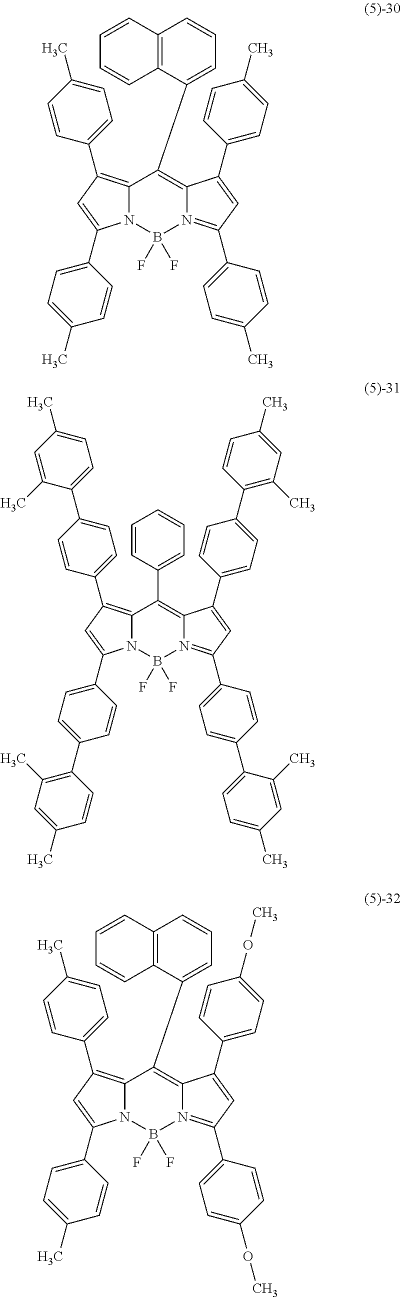

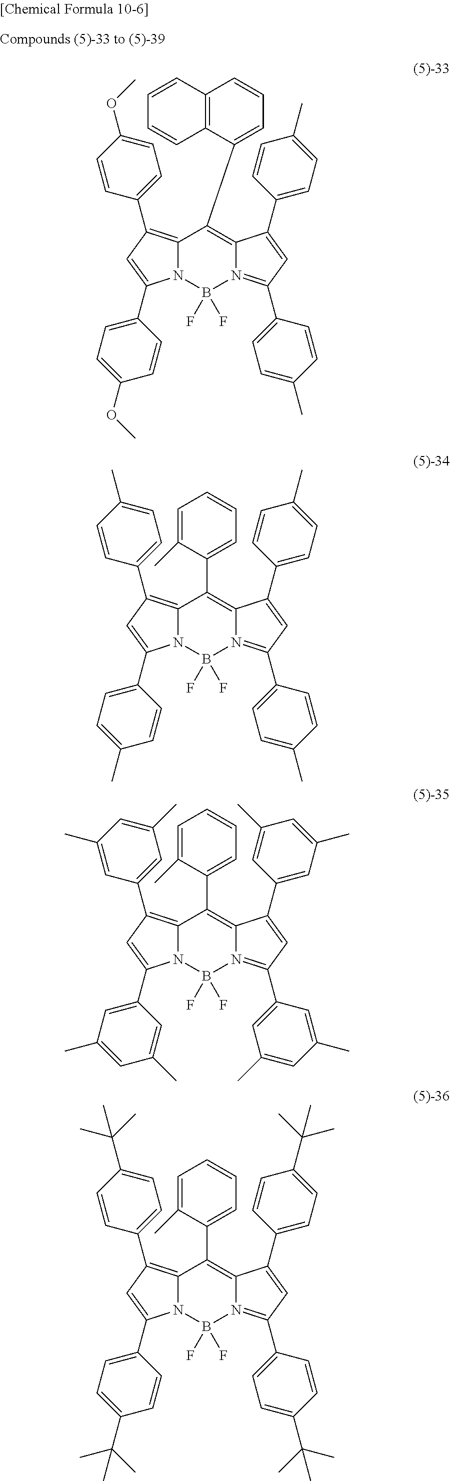

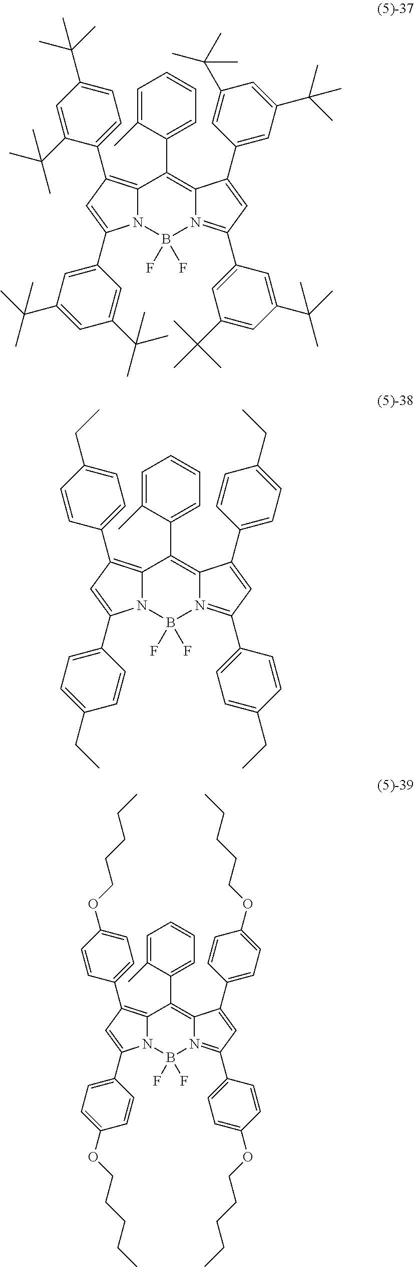

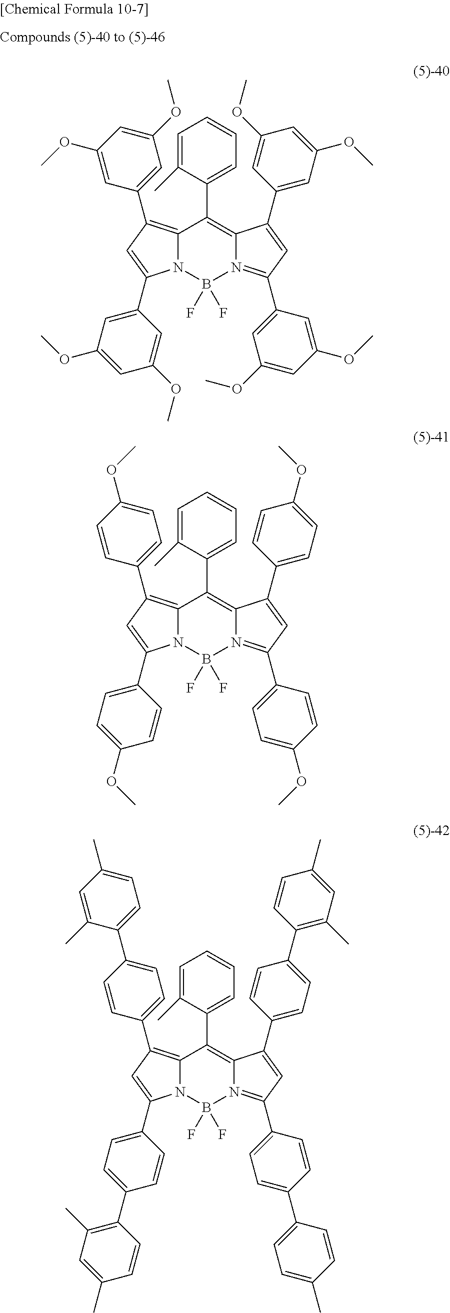

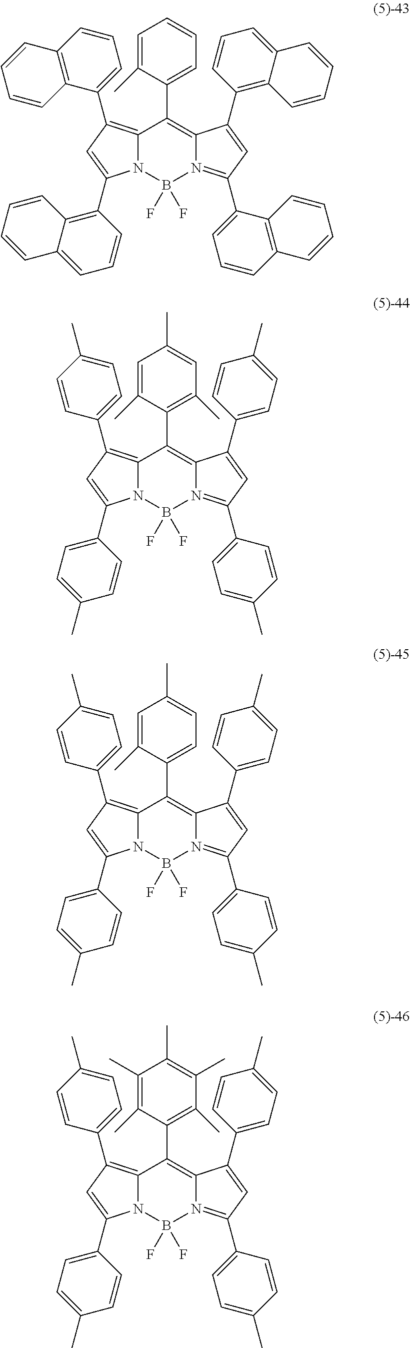

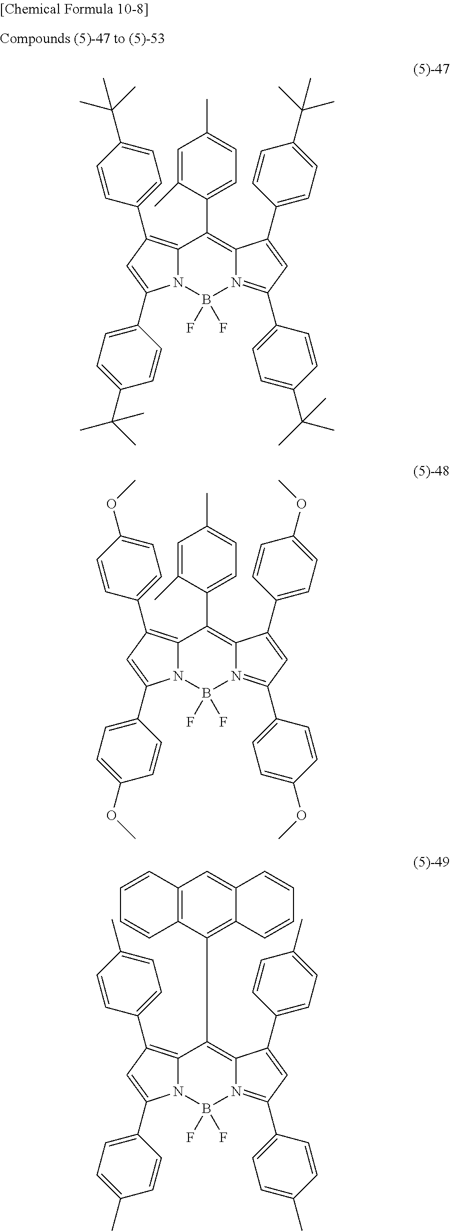

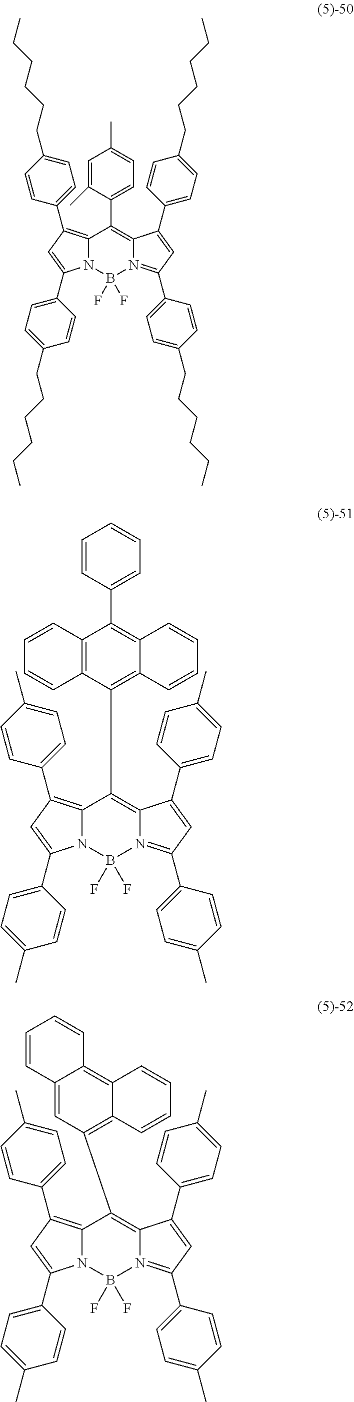

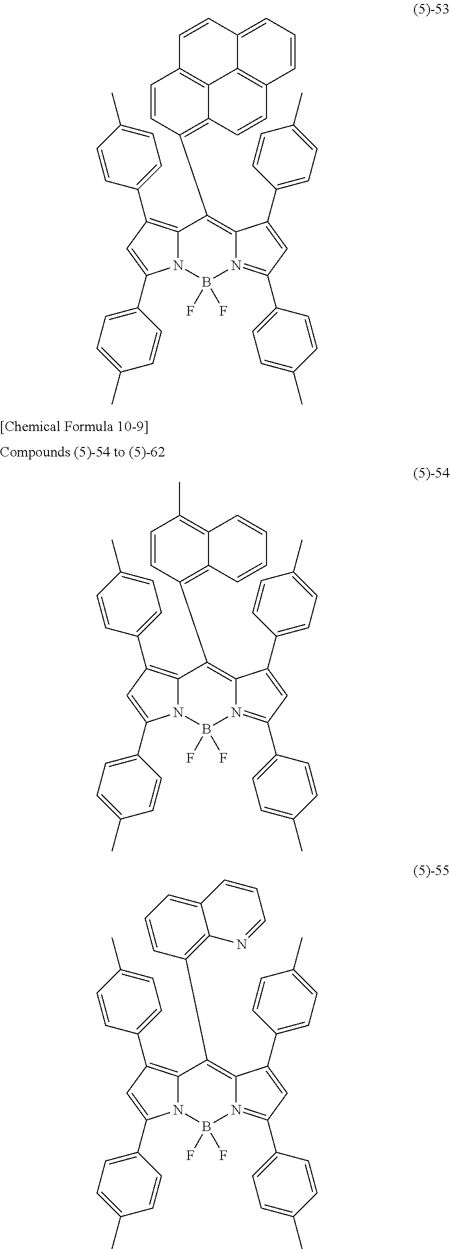

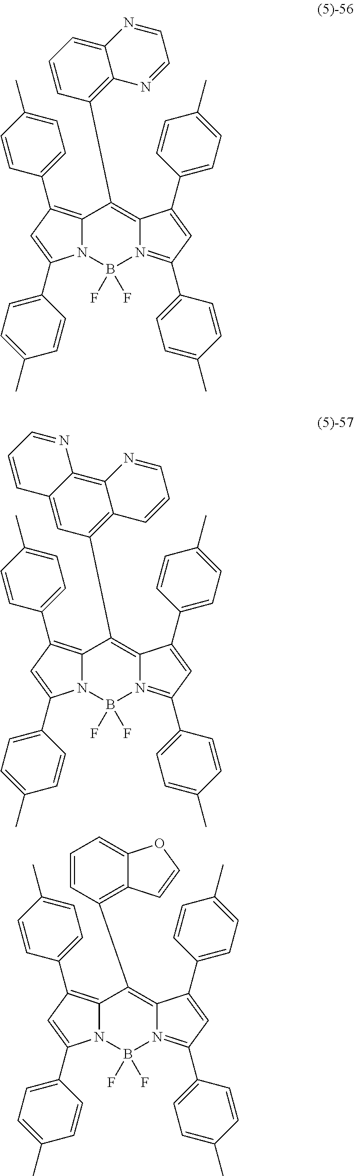

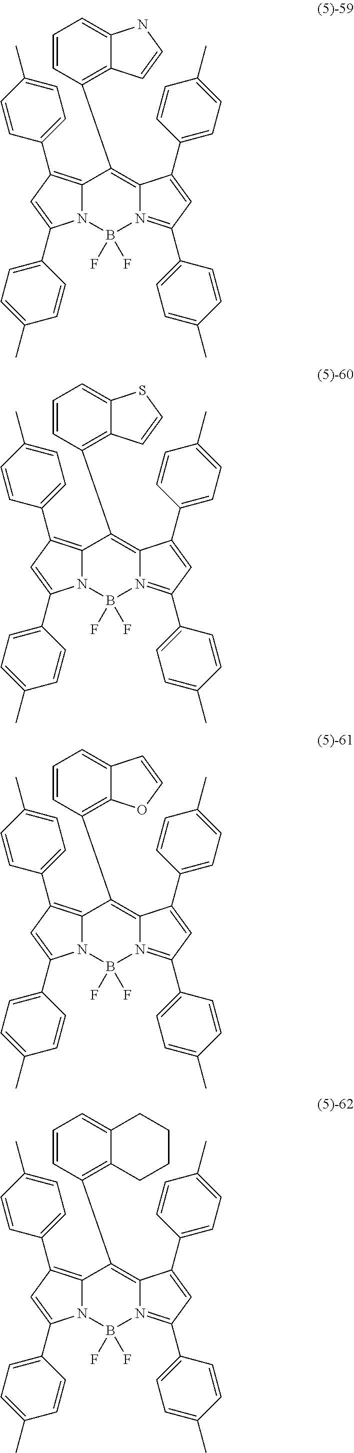

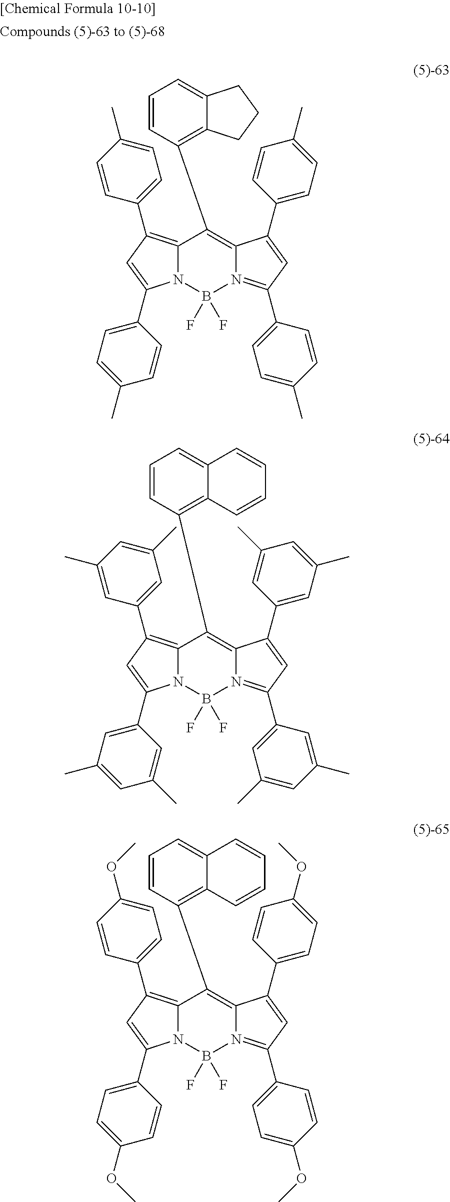

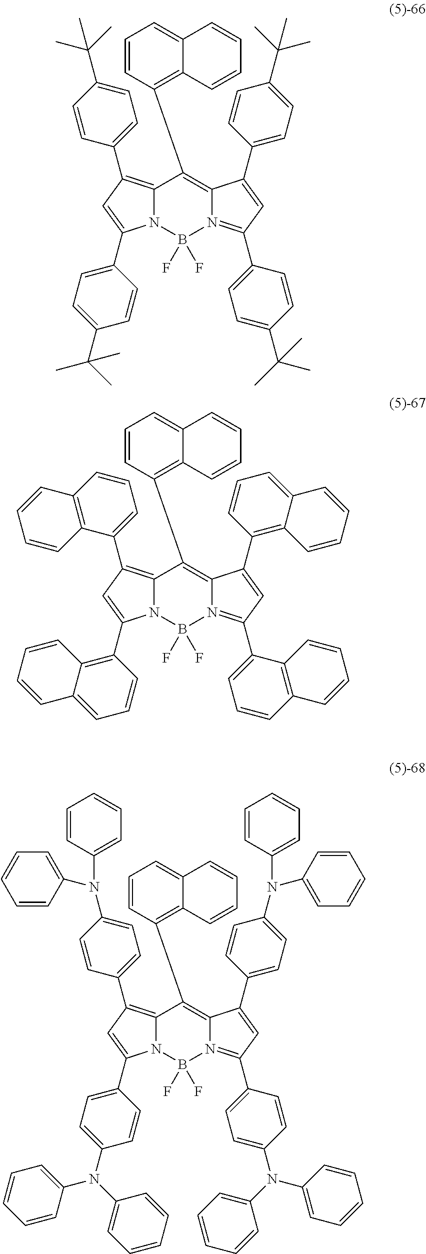

—Pyrane Derivative—

As the red light emitting guest material, for example, a compound (a pyrane derivative) represented by the following general formula (6) is used

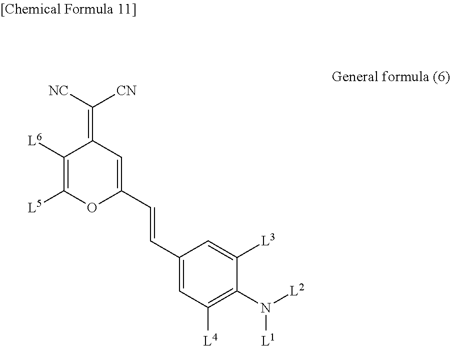

However, in the general formula (6), L¹ to L⁶ each independently represent hydrogen, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms. L¹ and L⁴, or L² and L³ may have a cyclic structure through a carbon hydride.

In addition, in the general formula (6), the substituted or unsubstituted aryl group represented by L¹ to L⁶, the heterocyclic group represented by L¹ to L⁶, and, the amino group represented by L¹ to L⁶ are the same as the group represented by the perylene derivative of the general formula (3). L¹ and L⁴, or L² and L³ may have the cyclic structure through the carbon hydride. In addition, two or more kinds of the above-described substituents may form a condensed ring, and may further have a substituent.

As specific examples of the pyrane derivative suitably used as the red light emitting guest material in the light emitting layer 14c, the following compounds (6)-1 to (6)-7 are exemplified. However, the present invention is not limited to these in any way.

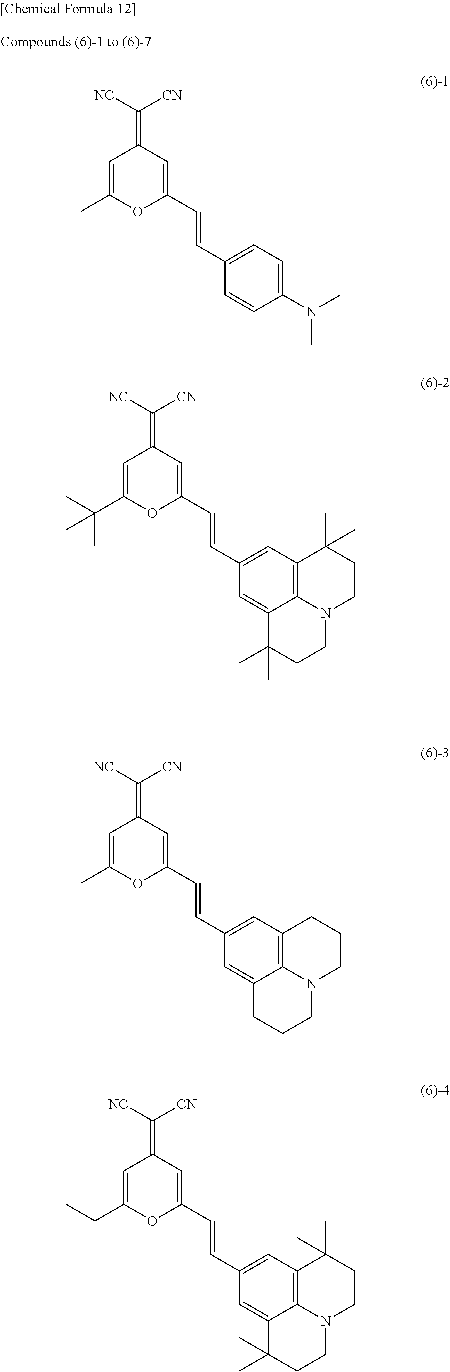

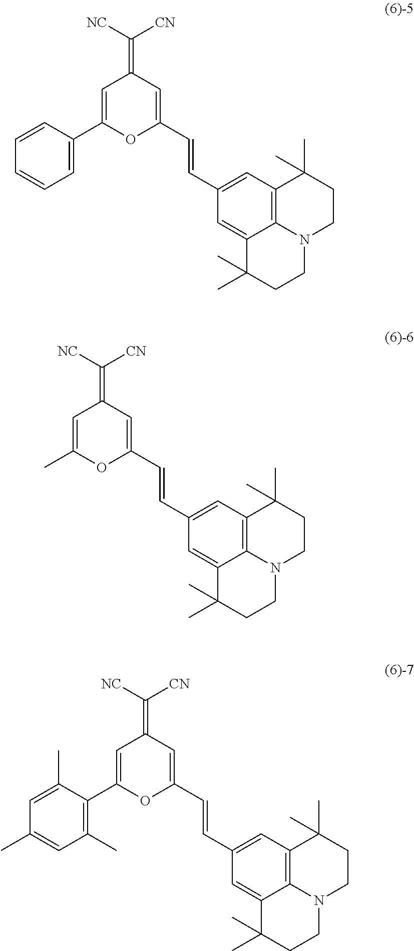

—Styryl Derivative—

As the red light emitting guest material, for example, a compound (a styryl derivative) represented by the following general formula (7) is used.

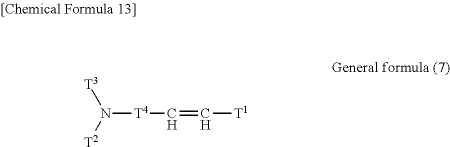

In the general formula (7), T¹ to T³ represent a substituted or unsubstituted aryl group having 30 or less carbon atoms, or a substituted or unsubstituted heterocyclic group having 30 or less carbon atoms. Moreover, T⁴ represents a substituted or unsubstituted phenylene portion which may have a cyclic structure with T² and T³.

In the general formula (7), the substituted or unsubstituted aryl group represented by T¹ to T³, and the heterocyclic group represented by T¹ to T³ are the same as the group represented by the perylene derivative of the general formula (3).

Two or more kinds of the above-described substituents may form a condensed ring, and may further have a substituent. In this case, as the group substituted by T¹ to T⁴, for example, hydrogen, halogen, a hydroxylamine group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, an amino group, or the like is cited. In addition to those, the amino group may be an alkylamino group, an arylamino group, an aralkylamino group, or the like. These preferably have an aliphatic group having a total of 1 to 6 carbon atoms and/or a monocyclic to tetracyclic aromatic carbon ring. As such a group, a dimethylamino group, a diethylamino group, a dibutylamino group, a diphenylamino group, a ditolylamino group, a bisbiphenylylamino group, or a dinaphthyl amino group is cited.

As specific examples of the styryl derivative suitably used as the red light emitting guest material in the light emitting layer 14c, the following compounds (7)-1 to (7)-35 are exemplified. However, the present invention is not limited to these in any way.

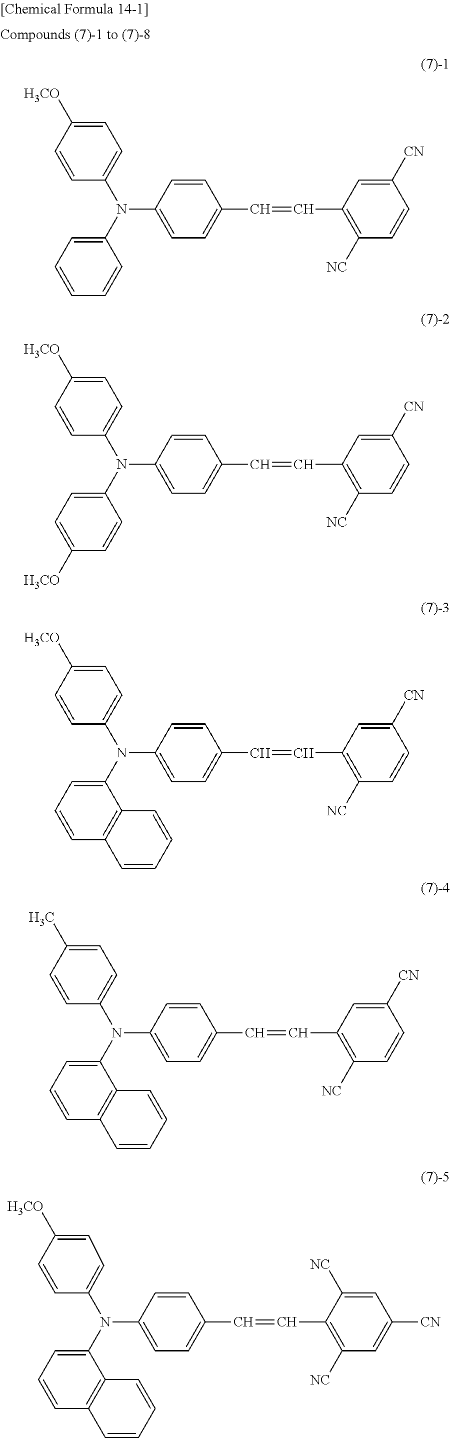

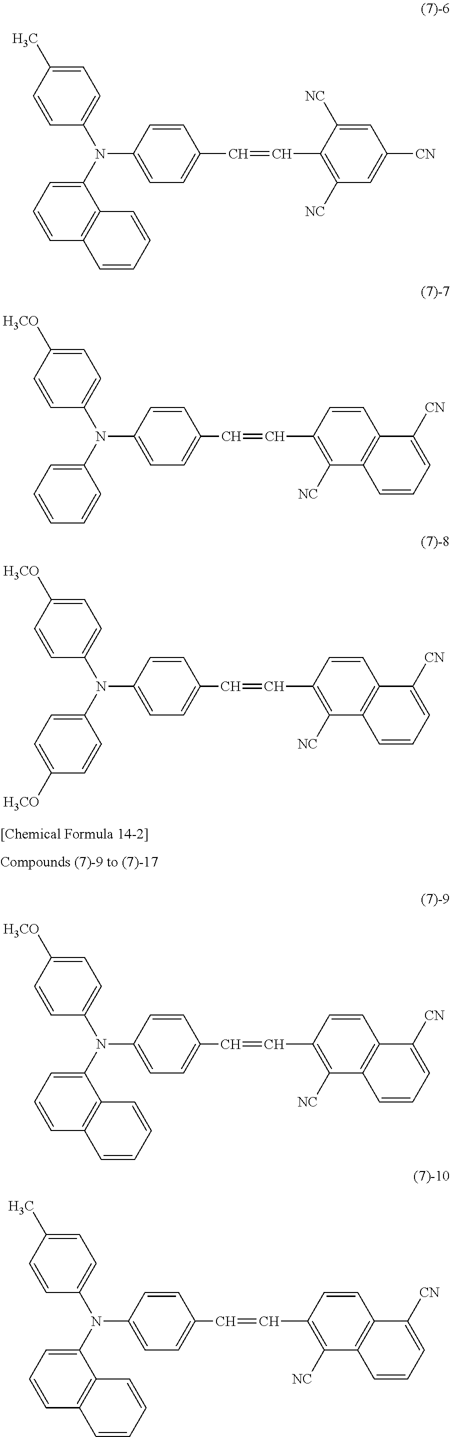

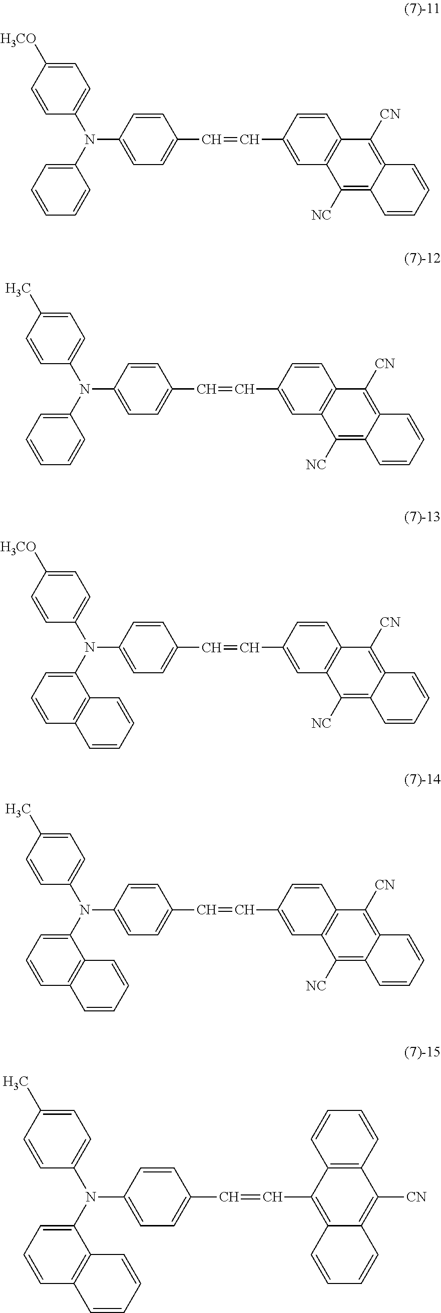

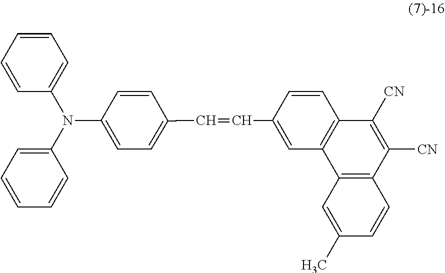

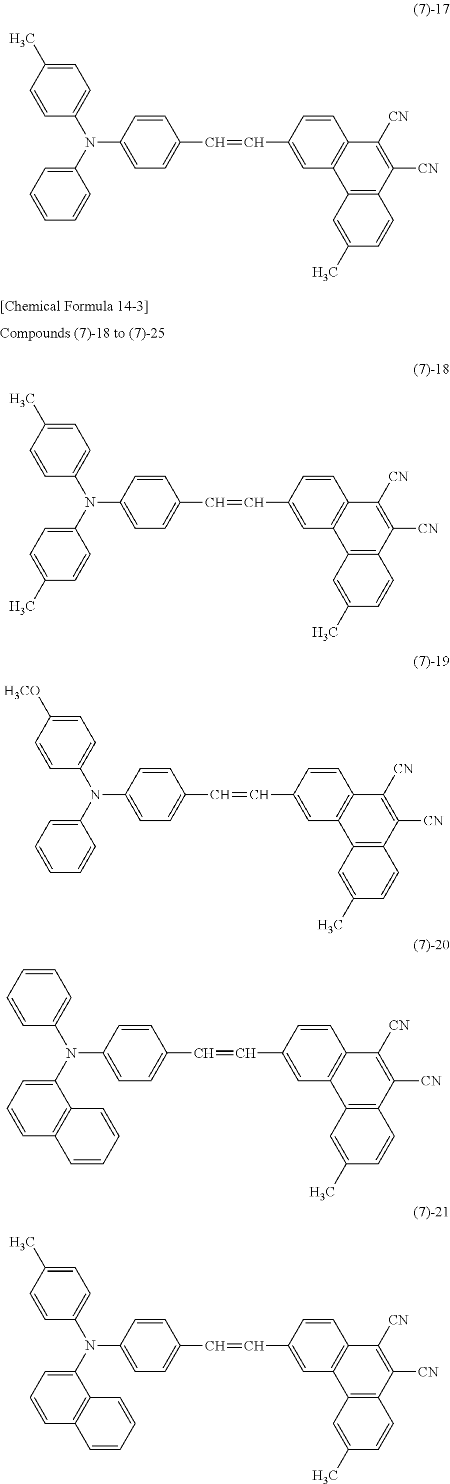

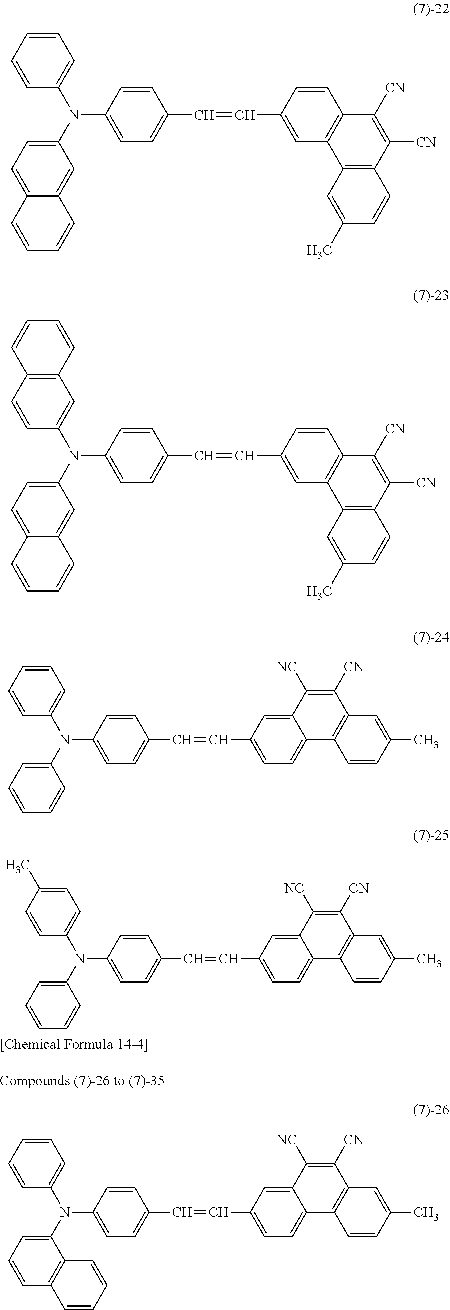

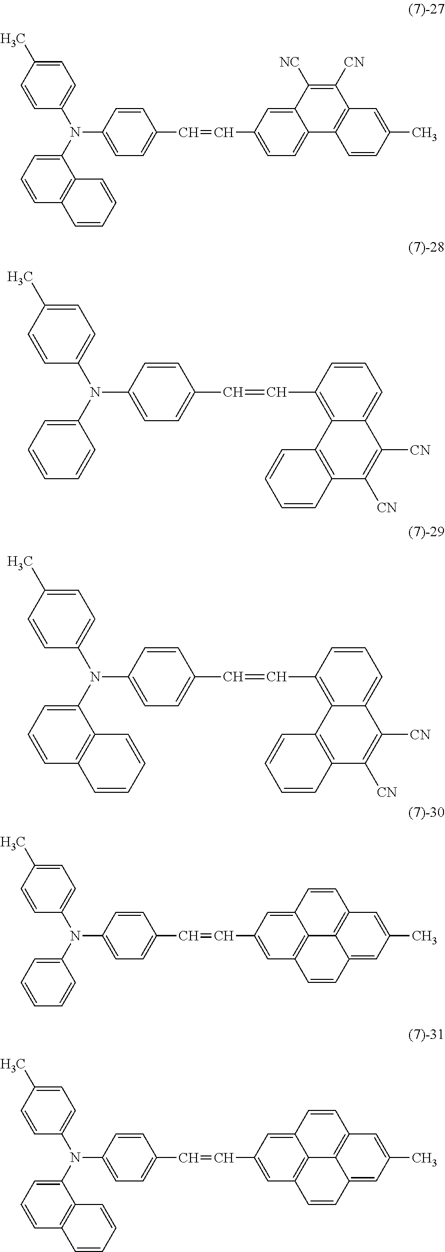

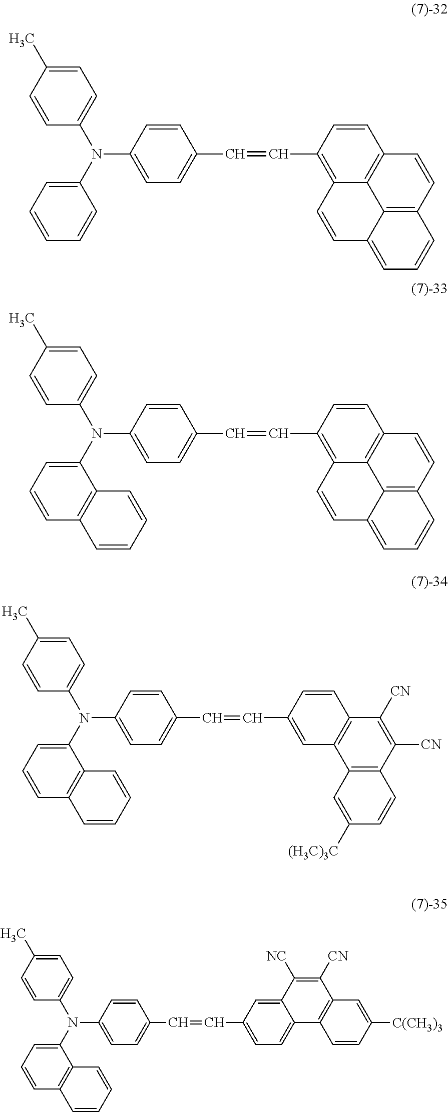

In addition, the perylene derivative of the general formula (3), the diketopyrrolopyrrole derivative of the general formula (4), the pyrromethene complex of the general formula (5), the pyrane derivative of the general formula (6), or the styryl derivative of the general formula (7) which is used as the red light emitting guest material in the light emitting layer 14c described above preferably has a molecular weight of 2000 or less, more preferably has a molecular weight of 1500 or less, and particularly preferably has a molecular weight of 1000 or less. The reason is that if the molecular weight is high, there is concern that evaporation characteristics deteriorate in the case where an element is fabricated by the evaporation.

<Electron Transport Layer>

The electron transport layer 14d is for transporting an electron injected from the cathode 15 to the light emitting layer 14c. This embodiment has characteristics in that the benzimidazole derivative represented by the general formula (1) is contained in the electron transport layer 14d.

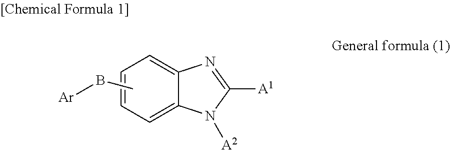

A¹ and A² in the general formula (1) each independently represent a hydrogen atom, a substituted or unsubstituted aryl group having 60 or less carbon atoms, a substituted or unsubstituted heterocyclic group, a substituted or unsubstituted alkyl group having 1 to 20 carbon atoms, or an alkoxy group having 1 to 20 carbon atoms.

B in the general formula (1) represents a substituted or unsubstituted arylene group having 60 or less carbon atoms, a pyridinylene group which may have a substituted group or an unsubstituted group, a quinolinylene group which may have a substituent, or a fluorenylene group which may have a substituent.

Ar in the general formula (1) represents a substituted or unsubstituted aryl group having 60 or less carbon atoms, a substituted or unsubstituted heterocyclic group, a substituted or unsubstituted alkyl group having 1 to 20 carbon atoms, or a substituted or unsubstituted alkoxy group having 1 to 20 carbon atoms.

Specific examples of such a benzimidazole derivative are shown in Tables 1-1 to 1-7 by diving components in the general formula (1) into quarters as shown below.

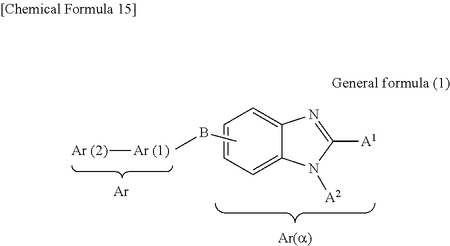

TABLE 1-1

| | | | Ar[—Ar(1)—Ar(2)] | |
|---|---|---|---|---|
| | Ar(α) | B | Ar(1) | Ar(2) |
| (1)-1 | 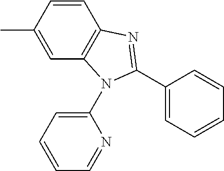 | 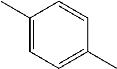 | 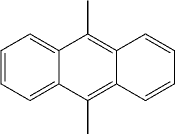 | 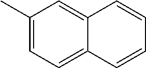 |
| (1)-2 | 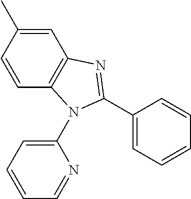 | 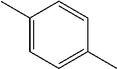 | 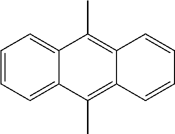 | 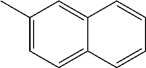 |
| (1)-3 | 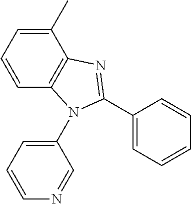 | 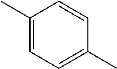 | 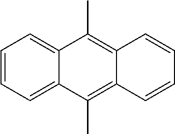 | 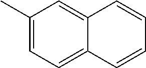 |
| (1)-4 | 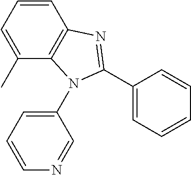 | 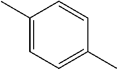 | 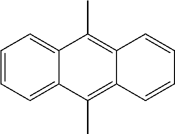 | 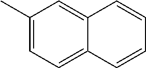 |
| (1)-5 | 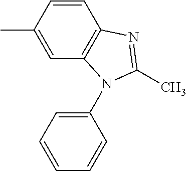 | 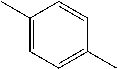 | 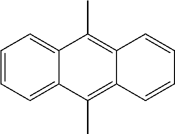 | 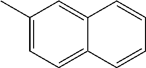 |
| (1)-6 | 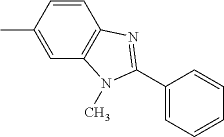 | 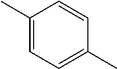 | 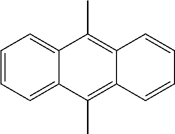 | 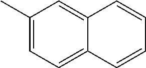 |
| (1)-7 | 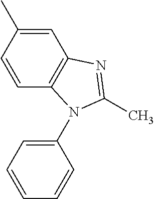 | 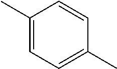 | 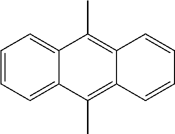 | 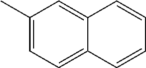 |
| (1)-8 | 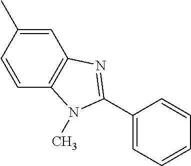 | 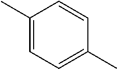 | 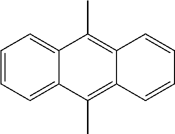 | 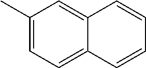 |
| (1)-9 | 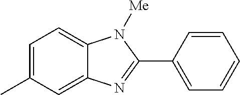 | 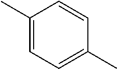 | 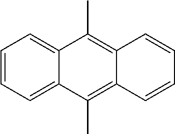 | 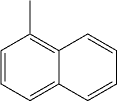 |
| (1)-10 | 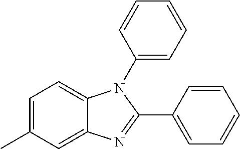 | 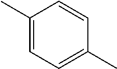 | 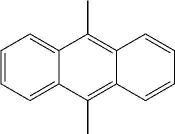 | 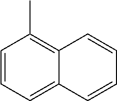 |

TABLE 1-2

| | | | Ar[—Ar(1)—Ar(2)] | |
|---|---|---|---|---|
| | Ar(α) | B | Ar(1) | Ar(2) |
| (1)-11 | 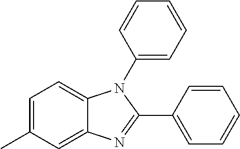 | 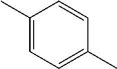 | 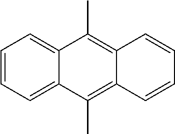 | 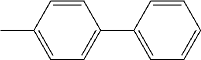 |
| (1)-12 | 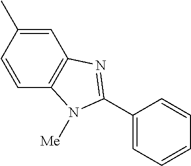 | 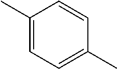 | 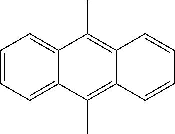 | 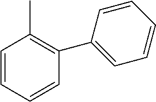 |
| (1)-13 | 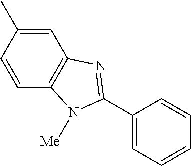 | 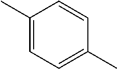 | 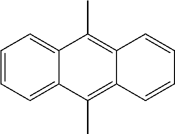 | 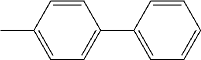 |
| (1)-14 | 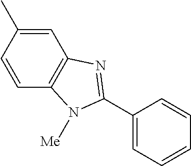 | 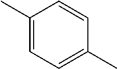 | 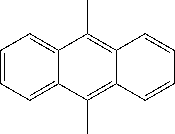 | 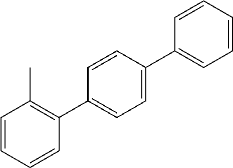 |
| (1)-15 | 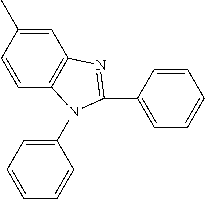 | 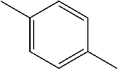 | 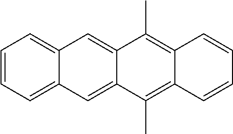 | 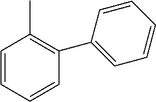 |
| (1)-16 | 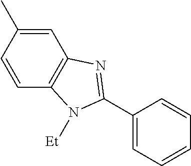 | 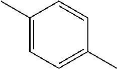 | 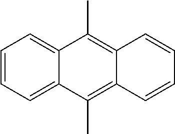 | 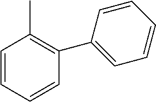 |
| (1)-17 | 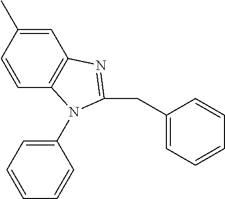 | 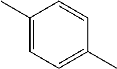 | 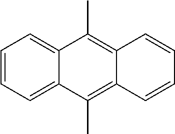 | 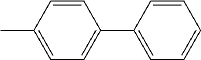 |
| (1)-18 | 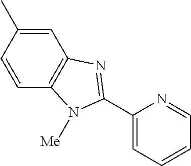 | 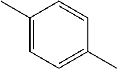 | 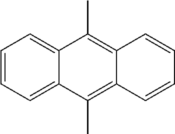 | 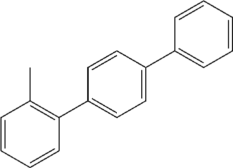 |

TABLE 1-3

| | | | Ar[—Ar(1)—Ar(2)] | |
|---|---|---|---|---|
| | Ar(α) | B | Ar(1) | Ar(2) |
| (1)-19 | 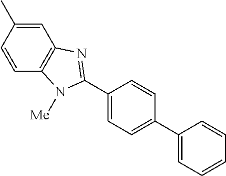 | 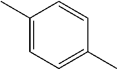 | 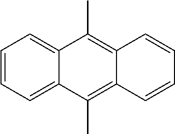 | 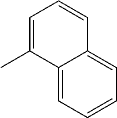 |
| (1)-20 | 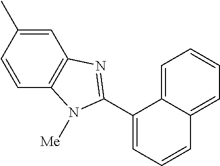 | 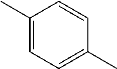 | 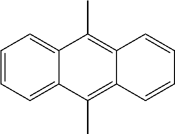 | 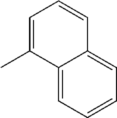 |
| (1)-21 | 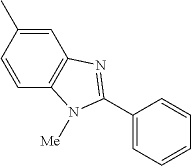 | 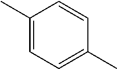 | 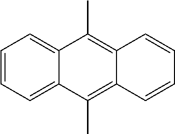 | 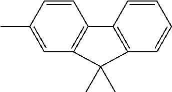 |
| (1)-22 | 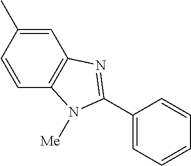 | 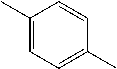 | 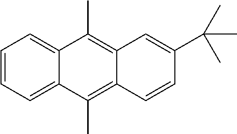 | 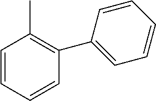 |
| (1)-23 | 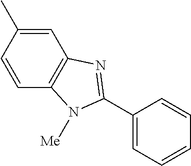 | 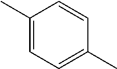 | 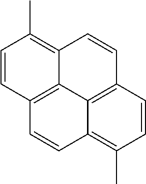 | 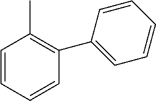 |
| (1)-24 | 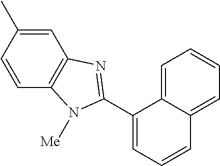 | 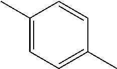 | 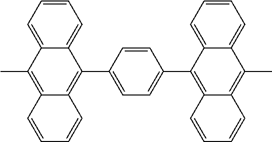 | 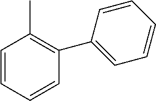 |

TABLE 1-4

| | Ar(α) | B | Ar |
|---|---|---|---|
| (1)-25 | 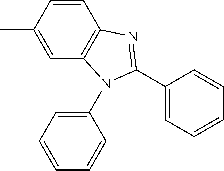 | 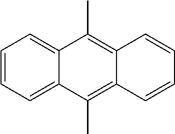 | 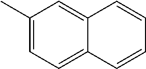 |
| (1)-26 | 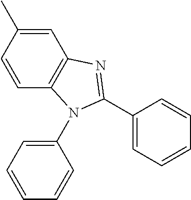 | 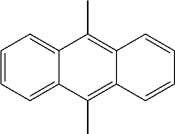 | 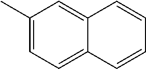 |
| (1)-27 | 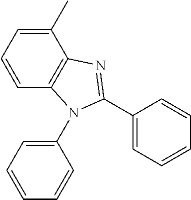 | 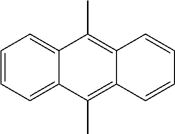 | 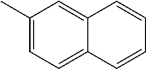 |
| (1)-28 | 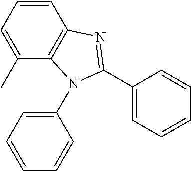 | 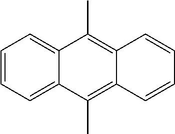 | 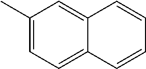 |
| (1)-29 | 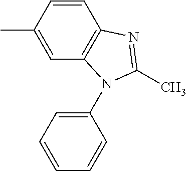 | 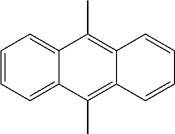 | 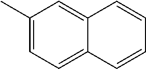 |
| (1)-30 | 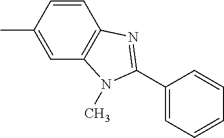 | 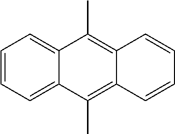 | 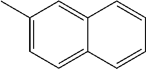 |
| (1)-31 | 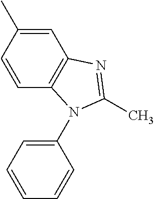 | 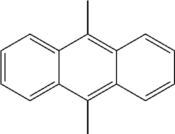 | 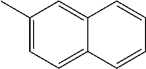 |
| (1)-32 | 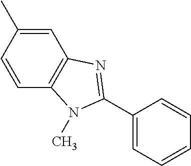 | 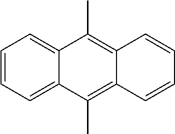 | 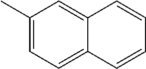 |

TABLE 1-5

| | Ar(α) | B | Ar |
|---|---|---|---|
| (1)-33 | 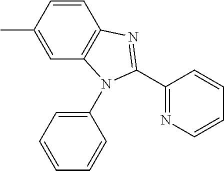 | 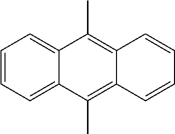 | 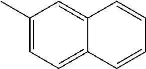 |
| (1)-34 | 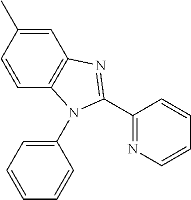 | 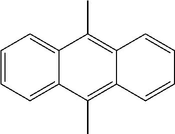 | 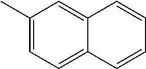 |
| (1)-35 | 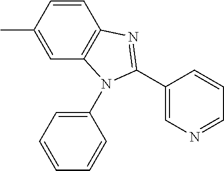 | 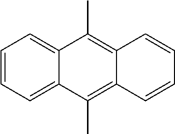 | 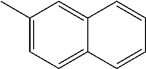 |
| (1)-36 | 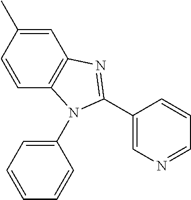 | 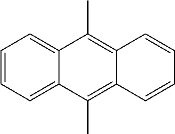 | 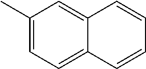 |
| (1)-37 | 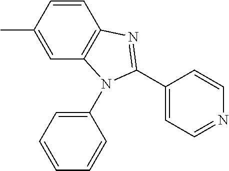 | 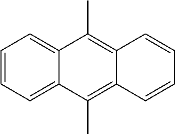 | 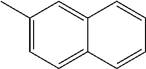 |
| (1)-38 | 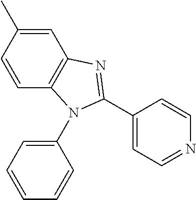 | 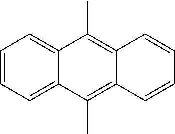 | 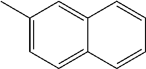 |
| (1)-39 | 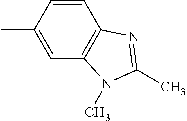 | 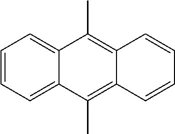 | 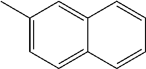 |
| (1)-40 | 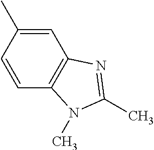 | 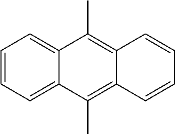 | 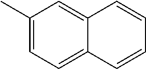 |

TABLE 1-6

| | Ar(α) | B | Ar |
|---|---|---|---|
| (1)-41 | 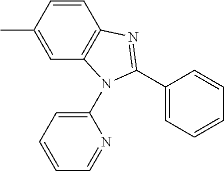 | 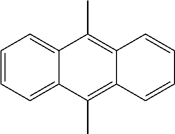 | 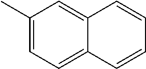 |
| (1)-42 | 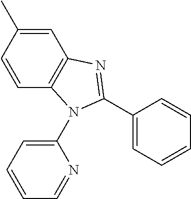 | 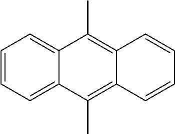 | 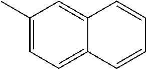 |
| (1)-43 | 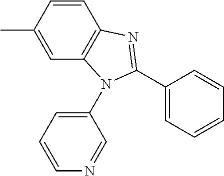 | 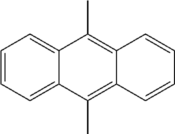 | 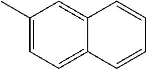 |
| (1)-44 | 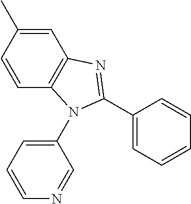 | 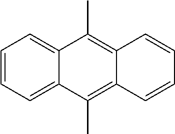 | 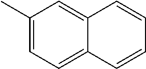 |
| (1)-45 | 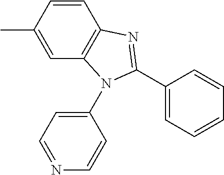 | 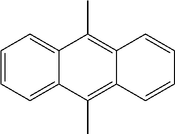 | 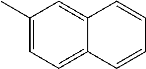 |
| (1)-46 | 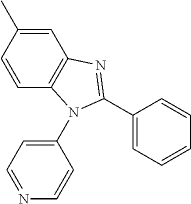 | 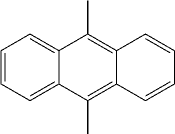 | 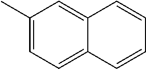 |
| (1)-47 | 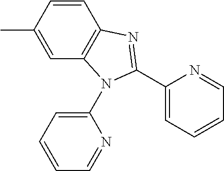 | 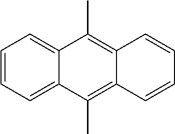 | 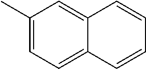 |
| (1)-48 | 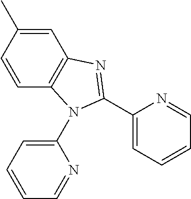 | 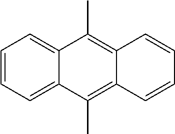 | 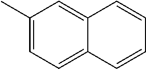 |

TABLE 1-7

| | | | Ar[—Ar(1)—Ar(2)] | |
|---|---|---|---|---|
| | Ar(α) | B | Ar(1) | Ar(2) |
| (1)-49 | 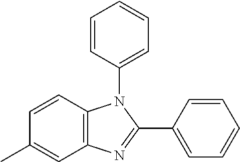 | 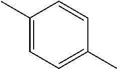 | 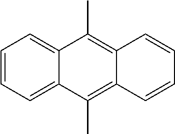 | 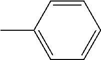 |
| (1)-50 | 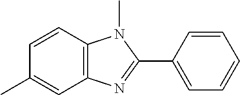 | 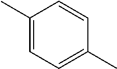 | 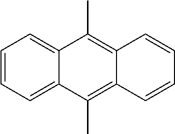 | 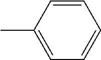 |
| (1)-51 | 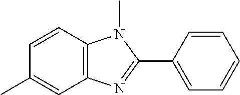 | 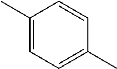 | 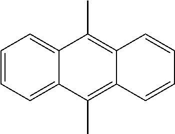 | 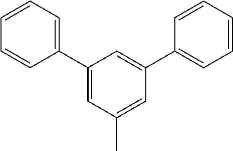 |
| (1)-52 | 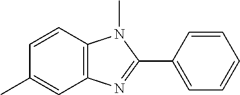 | 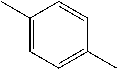 | 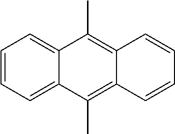 | 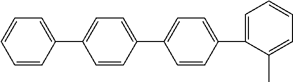 |
| (1)-53 | 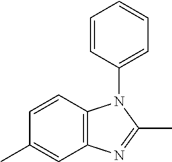 | 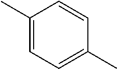 | 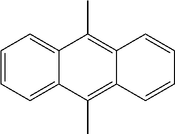 | 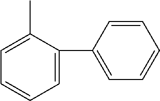 |
| (1)-54 | 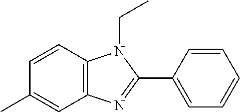 | 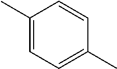 | 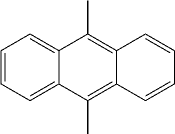 | 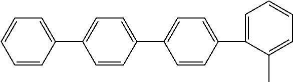 |

Further, as specific examples of the benzimidazole derivative represented by the general formula (1), the following compounds (1)-55 to (1)-65 can be shown.

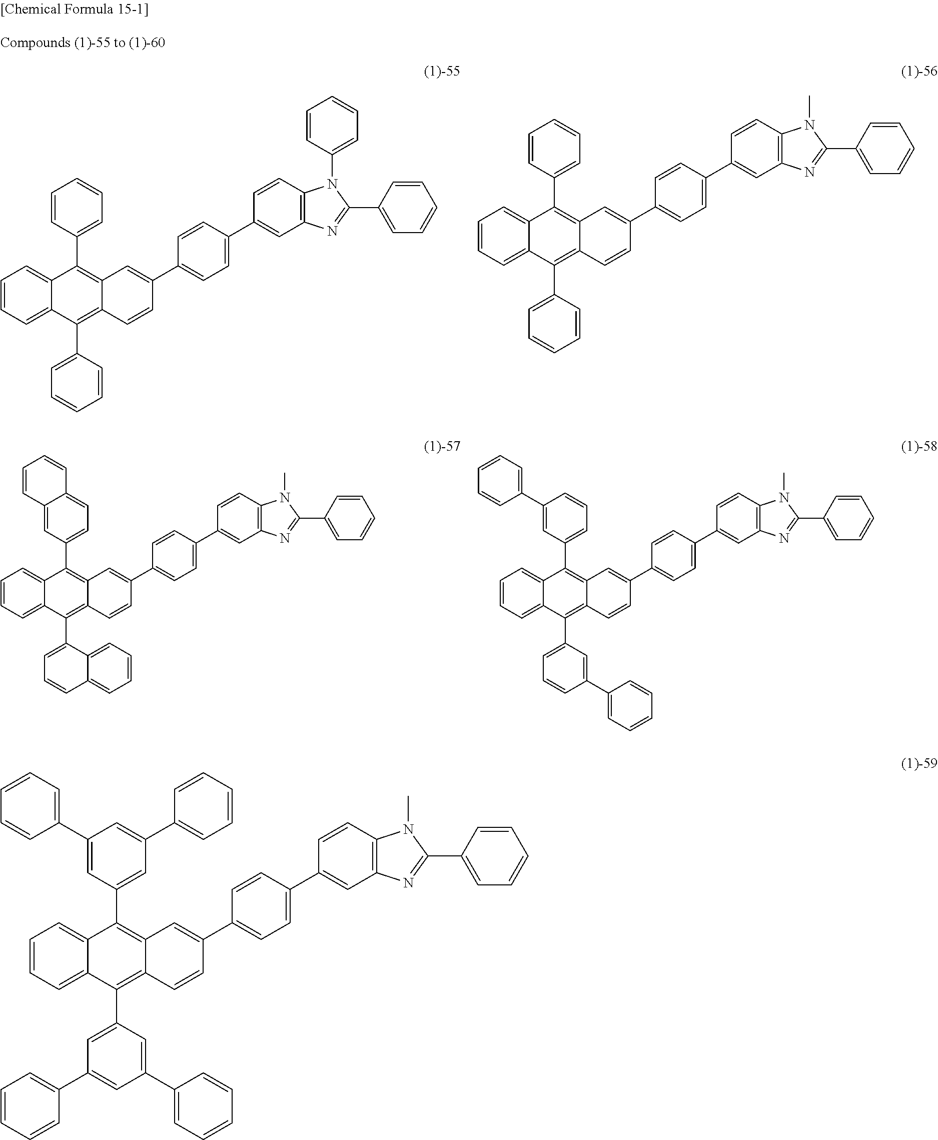

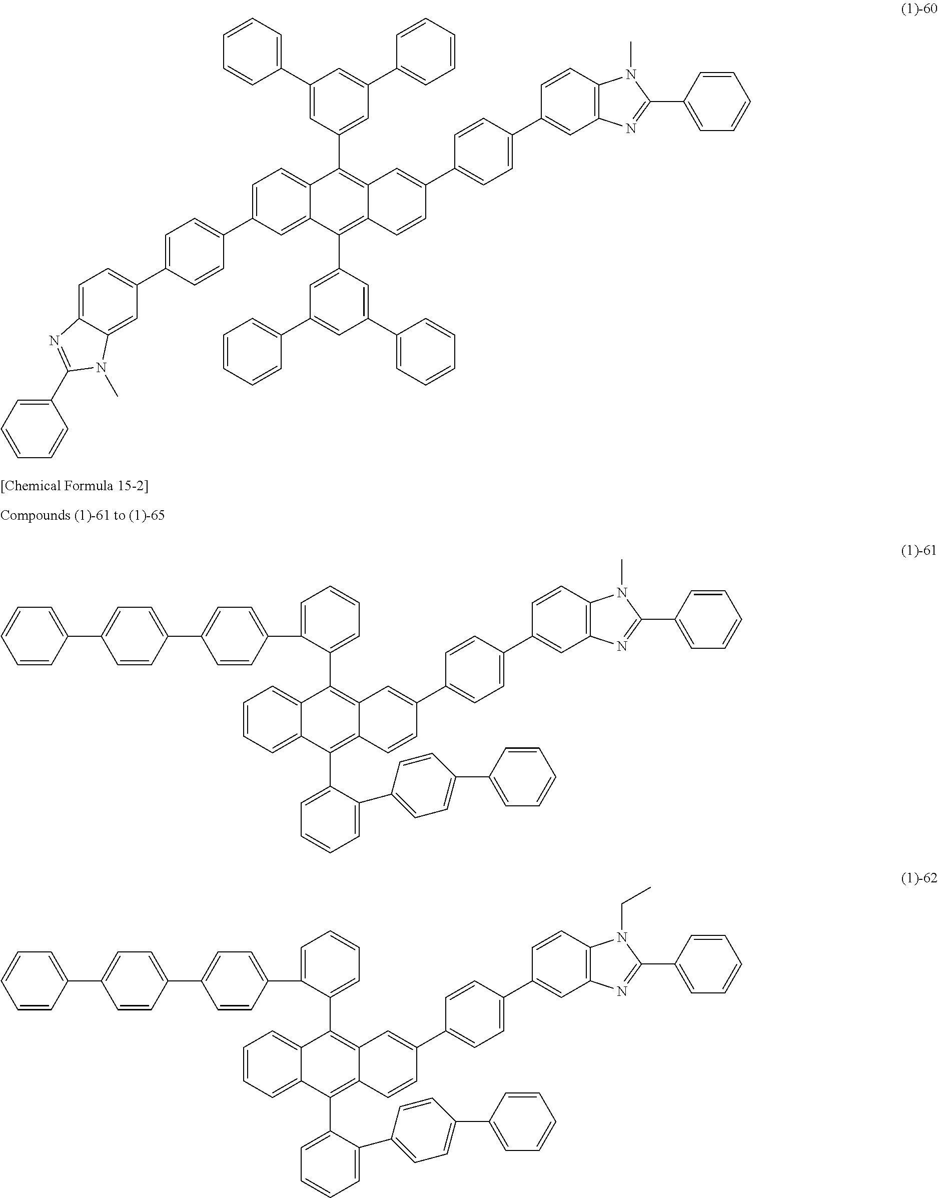

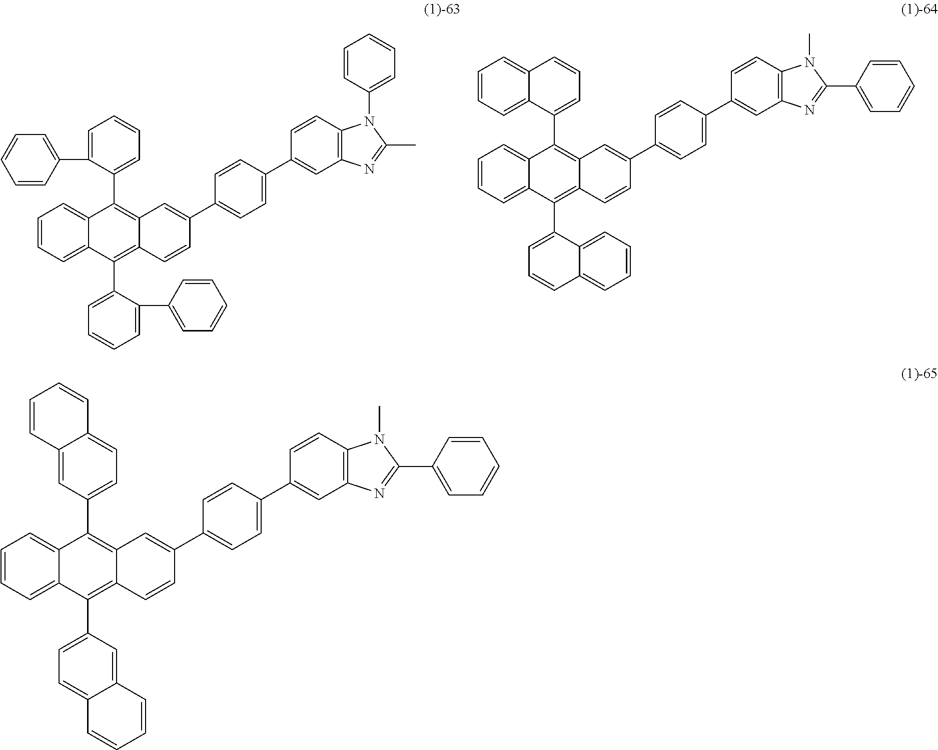

As represented by these compounds (1)-55 to (1)-65, as preferable examples of the benzimidazole derivative represented by the general formula (1), the structure in which B in the general formula (1) is a phenylene group, in particular, a paraphenylene group is exemplified. Moreover, Ar in the general formula (1) is an anthracene ring which may have a substituent, and is preferably bonded to the phenylene group of B in the general formula (1) at the 2-position and 6-position of the anthracene ring. In addition, the substituent bonded to the anthracene ring is preferably bonded to the anthracene ring at the 9-position and 10-position as exemplified in the above-described compounds (1)-55 to (1)-65. Such a substituent is preferably an aryl group having 6 to 40 carbon atoms, which may have a substituent, or a heteroaryl group having 3 to 40 carbon atoms, which may have a substituent.

The electron transport layer 14d constituted of such a benzimidazole derivative has characteristics to abundantly supply electrons to the light emitting layer 14c.

It is enough if the electron transport layer 14d contains at least one kind of the benzimidazole derivative, or the electron transport layer 14d may contain a plurality of kinds of the benziimidazole derivatives. In this case, the plurality of kinds of the benzimidazole derivatives may be contained in the electron transport layer 14d having a single layer structure. Moreover, the electron transport layer 14d may be constituted by stacking layers constituted of different kinds of the benzimidazole derivatives. Further, the electron transport layer 14d may be constituted of a combination of these. In the case where the layers containing the plurality of kinds of the benzimidazole derivatives are provided in the electron transport layer 14d, the plurality of kinds of the benzimidazole derivatives may be co-evaporated.

The organic layer 14 constituted of each layer as described above is not limited to such a layer structure as long as it is a structure in which the red light emitting layer 14c containing the polycyclic aromatic hydrocarbon compound with the mother skeleton having 4 to 7 ring members as the host material, and the electron transport layer 14d containing the benzimidazole derivative which has been described by using the general formula (1) are provided in contact with each other.

For example, each layer constituting the organic layer 14 described above, for example, each of the hole injection layer 14a, the hole transport layer 14b, the light emitting layer 14c, and the electron transport layer 14d may have a stacked structure of a plurality of layers.

<Cathode>

The cathode 15 provided on the organic layer 14 having such a structure is, for example, constituted by a two-layer structure in which a first layer 15a, and a second layer 15b are stacked in this order from the organic layer 14 side.

The first layer 15a is constituted by using a material having a low work function, and favorable light transmittance.

As such materials, for example, a lithium oxide (Li₂O) as being an oxide of lithium (Li), a cesium carbonate (Cs₂CO₃) as being a composite oxide of cesium (Cs), and, further, a mixture of these oxide and composite oxide may be used. Moreover, the first layer 15a is not limited to such materials, and, for example, an alkali earth metal such as calcium (Ca) and barium (Ba), an alkali metal such as lithium and cesium, further, a metal having a low work function such as indium (In) and magnesium (Mg), further, a single substance of an oxide, a composite oxide, a fluoride, and the like of these metals, or a mixture or an alloy of an oxide, a composite oxide, and a fluoride of these metals improving the stability may be used.

The second layer 15b is, for example, constituted of a thin film using a layer having the light transmittance, such as MgAg. Further, the second layer 15b may be a mixed layer containing an organic light emitting material such as an alumiquinoline complex, a styrylamine derivative, and a phthalocyanine derivative. In this case, a layer having the light transmittance, such as MgAg, may be included separately as a third layer.

In the case where the drive method of the display device constituted by using the organic electroluminescent element 11 is the active matrix method, the above-described cathode 15 is formed in a solid film shape on the substrate 12 in the state of being insulated from the anode 13 by the organic layer 14 and the above-described insulating film (not illustrated in the figure), and is used as a common electrode of each pixel.

The cathode 15 is not limited to the stacked structure described above. Needless to say, the cathode 15 may apply an optimal combination and an optimal stacked structure according to the structure of a device to be manufactured. For example, the structure of the cathode 15 in this embodiment is the stacked structure in which functions of each layer in the electrode is separated, that is, an inorganic layer (the first layer 15a) facilitating the electron injection to the organic layer 14, and an inorganic layer (the second layer 15b) controlling the electrode are separated. However, the inorganic layer facilitating the electron injection to the organic layer 14 may also serve as the inorganic layer controlling the electrode, or these layers may be constituted as a single layer structure. Moreover, a stacked structure in which a transparent electrode of ITO or the like is formed on this single layer structure may be adopted.

A current applied to the organic electroluminescent element 11 having the above-described structure is typically a direct current, but a pulse current and an alternate current may be used. The current value and the voltage value are not specifically limited as long as they are within a range that an element is not damaged, but it is desirable for the organic electroluminescent element to efficiently emit light by electrical energy as low as possible, in consideration of the power consumption and the lifetime of the organic electroluminescent element.

In the case where the organic electroluminescent element 11 has the cavity structure, the cathode 15 is constituted by using a semitransparent semireflecting material, and the emitted light multiply-interfered between a light reflecting face on the anode 13 side, and a light reflecting face on the cathode 15 side is extracted from the cathode 15 side. In this case, the optical distance between the light reflecting face on the anode 13 side and the light reflecting face on the cathode 15 side is defined by a wavelength of the light desired to be extracted, and the film thickness of each layer is set so that this optical distance is satisfied. In such an organic electroluminescent element of the top emission type, it is possible to improve the light extraction efficiency to outside, and control the light emission spectrum by actively using the cavity structure.

Further, although omitted in the figure here, the organic electroluminescent element 11 having such as structure is preferably used in the state of being covered with a protective layer (a passivation layer) to prevent deterioration of the organic material caused by moisture, oxygen, or the like in the air. As the protective film, a silicon nitride (typically, Si₃N₄) film, a silicon oxide (typically, SiO₂) film, a silicon nitride oxide (SiNxOy: composition ratio X>Y) film, a silicon oxide nitride (SiOxNy: composition ration X>Y) film, a thin film containing carbon such as DLC (Diamond likeCarbon) as a main component, a CN (Carbon Nanotube) film, or the like is used. These films preferably have a single layer structure or a stacked structure. Among them, because the protective film of the nitride has a dense film-quality, and has a high blocking effect to moisture, oxygen and other impurities adversely influencing the organic electroluminescent element 11, the protective film of the nitride is preferably used.

In this embodiment, the present invention has been described in detail by exemplifying the case where the organic electroluminescent element is the top emission type. However, the organic electroluminescent element of the present invention is not limitedly applied to the top emission type, but is widely applicable to the structure in which the organic layer including at least the light emitting layer is held between the anode and the cathode. Accordingly, the organic electroluminescent element of the present invention is applicable to an organic electroluminescent element having a structure in which the cathode, the organic layer, and the anode are sequentially stacked in this order from the substrate side, and an organic electroluminescent element of a bottom emission type (a so-called transmission type) in which an electrode (a lower electrode as the cathode or the anode) positioned on the substrate side is constituted of a transparent material, and an electrode (an upper electrode as the cathode or the anode) positioned on the opposite side to the substrate is constituted of a reflecting material so that the light is extracted only from the lower electrode side.

Further, it is enough if the organic electroluminescent element of the present invention is an element formed by forming a pair of electrodes (the anode and the cathode), and holding the organic layer between those electrodes. Thus, it is not limited to an element constituted of only the pair of electrodes and the organic layer, and it does not exclude that other components (for example, an inorganic compound layer and an inorganic component) are coexistent within a range that the effects of the present invention are not lost.

In the organic electroluminescent element 11 having the above-described structure, as will be described later in detail in examples, it was confirmed that the current efficiency (light emission efficiency) was more improved and the lifetime was longer compared with that of the structure using the electron transport layer of related art.

It is thought that this is because the electrons are abundantly supplied to the light emitting layer 14c by providing the electron transport layer 14d constituted of the benzimidazole derivative, adjacent to the red light emitting layer 14c. Thereby, most of the holes supplied from the hole transport layer 14b to the light emitting layer 14c are recombined with a large amount of electrons supplied from the electron transport layer 15d in the light emitting layer 14c, and contribute to light emission in the light emitting layer 14c. Therefore, the light emission efficiency is improved, and it is possible to obtain favorable, highly-pure red light emission only by the light emission of the light emitting layer 14c, while the recombination region of the electrons and the holes is efficiently suppressed only in the light emitting layer 14c.

From the above, according to the organic electroluminescent element 11 having the above-described structure, it is possible to realize improvement of the light emission efficiency of the red light emission and long lifetime, while color purity is maintained.

By such a drastic improvement of the light emission efficiency, it is possible to achieve improvement of the luminance lifetime and reduction of the power consumption of the organic electroluminescent element 11.

<<Schematic Structure of Display Device>>

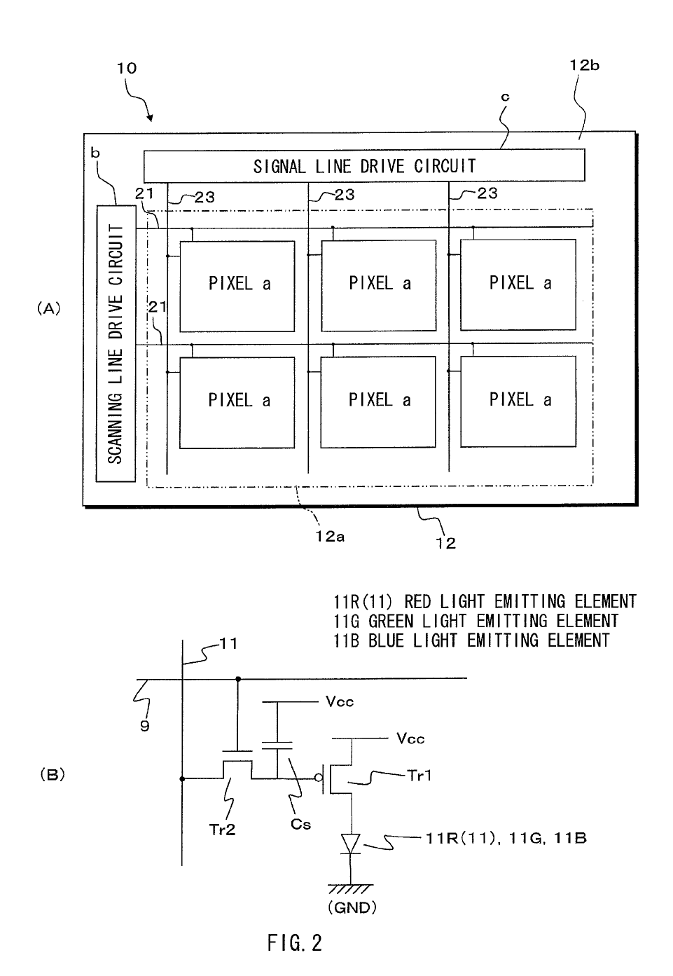

FIG. 2 is a view illustrating an example of an active matrix type display device 10 using the above-described organic electroluminescent element 11. FIG. 2(A) is a schematic structure view, and FIG. 2(B) is a structure view of a pixel circuit.

As illustrated in FIG. 2(A), a display region 12a and a surrounding region 12b of the display region 12a are set on the substrate 12 of the display device 10. In the display region 12a, a plurality of scanning lines 21 and a plurality of signal lines 23 are vertically and horizontally disposed, and the display region 12a is constituted as a pixel array section in which a pixel a is provided corresponding to each of intersections. In each pixel a, one of organic electroluminescent elements 11R (11), 11G, and 11B is provided. In the surrounding region 12b, a scanning line drive circuit b scanning and driving the scanning line 21, and a signal line drive circuit c supplying a picture signal (that is, an input signal) corresponding to luminance information to the signal line 23 are disposed.

As illustrated in FIG. 2(B), for example, the pixel circuit provided in each pixel a is constituted of the one of the organic electroluminescent elements 11R (11), 11G, and 11B, a drive transistor Tr1, a write transistor (sampling transistor) Tr2, and a retention capacity Cs. Further, the picture signal written from the signal line 23 through the write transistor Tr2 is held in the retention capacity Cs by drive of the scanning line drive circuit b, and a current corresponding to the held signal amount is supplied to each of the organic electroluminescent elements 11R (11), 11G, and 11B. The organic electroluminescent elements 11R (11), 11G, and 11B emit light at the luminance corresponding to this current value.

The structure of the pixel circuit described above is just an example. If necessary, the pixel circuit may be constituted by providing a capacitance element, and, further, providing a plurality of transistors in the pixel circuit. Moreover, a necessary drive circuit is added to the surrounding region 2b according to changes of the pixel circuit.

<<Structural Example of Cross-Section of Display Device>>

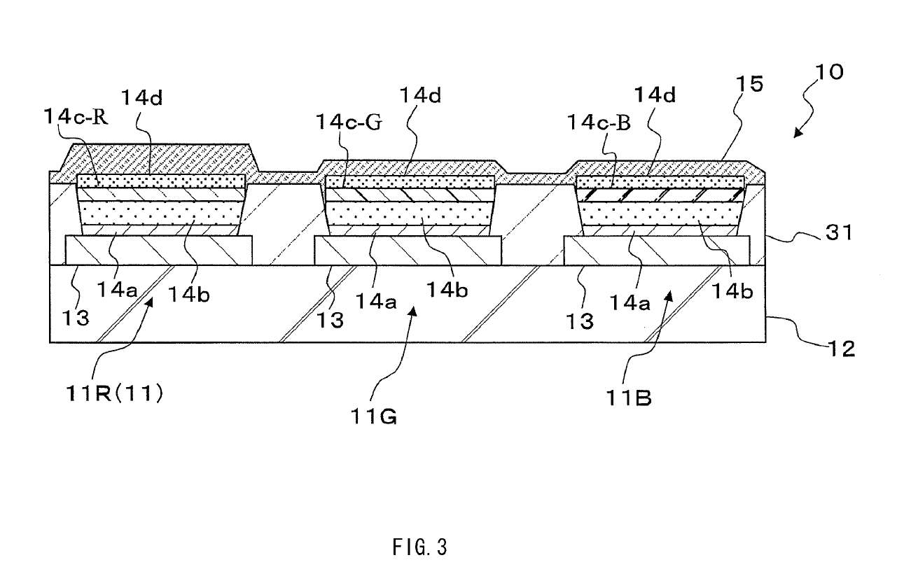

FIG. 3 illustrates an example of the cross-sectional structure of a main part in the display region of the display device 10.

In the display region of the substrate 12 in which the organic electroluminescent elements 11R (11), 11G, and 11B are provided, although omitted in the figure here, the drive transistor, the write transistor, the scanning line, and the signal line are provided to constitute the above-described pixel circuit (refer to FIG. 2), and an insulating film is provided in the state of covering the drive transistor, the write transistor, the scanning line, and the signal line.

The organic electroluminescent elements 11R (11), 11G, and 11B are formed and aligned on the substrate 12 covered with this insulating film. Each of the organic electroluminescent elements 11R (11), 11G, and 11B is constituted as a top emission type element in which the light is extracted from the opposite side to the substrate 12.

The anode 13 of each of the organic electroluminescent elements 11R (11), 11G, and 11B is pattern-formed for each element. Each anode 13 is connected to the drive transistor of the pixel circuit through a connection hole formed in the insulating film covering the surface of the substrate 12.

In each anode 13, its surrounding portion is covered with the insulating film 31, and a middle portion of the anode 13 is exposed to the aperture portion provided in the insulating film 31. Then, the organic layer 14 is pattern-formed in the state of covering the exposed portion of the anode 13, and the cathode 15 is provided as a common layer covering each organic layer 14.

In the organic electroluminescent elements 11R (11), 11G, and 11B, in particular, the red light emitting element 11R is constituted as the organic electroluminescent element (11) of this embodiment which has been described by using FIG. 1. On the other hand, the green light emitting element 11G and the blue light emitting element 11B may have a typical element structure.

In other words, in the organic layer 14 provided on the anode 13 in the red light emitting element 11R (11), for example, the hole injection layer 14a, the hole transport layer 14b, a red light emitting layer 14c-R (14c) using the naphthacene derivative as the host material, and the electron transport layer 14d are stacked in this order from the anode 13 side.

Meanwhile, in the organic layer in the green light emitting element 11G and the blue light emitting element 11B, for example, the hole injection layer 14a, the hole transport layer 14b, a light emitting layers 14c-G or a light emitting layer 14c-B of each color, and the electron transport layer 14d are stacked in this order from the anode 13 side.

Further, the plurality of organic electroluminescent elements 11R (11), 11G, and 11B provided in the above-described manner are covered with a protective film. In addition, this protective film is provided to cover the whole display region in which the organic electroluminescent elements 11R, 11G, and 11B are provided.

Here, each layer from the anode 13 to the cathode 15 constituting the red light emitting element 11R (11), the green light emitting element 11G, and the blue light emitting element 11B can be formed by a dry process such as a vacuum evaporation method, an ion beam method (EB method), a molecular beam epitaxy method (MBE method), a sputtering method, and an OVPD (Organic Vapor Phase Deposition) method.

Moreover, if it is an organic layer, in addition to the above-described methods, formation by a laser transfer method, a wet process including a coating method such as a spin coating method, a dipping method, a doctor blade method, a discharge coating method, and a spray coating method, and a printing method such as an inkjet method, an offset printing method, an anastatic printing method, an intaglio printing method, a screen printing method, and a micro gravure coating method, or the like is possible, and a dry process and a wet process may be used in combination according to characteristics of each organic layer and each member.

Then, the organic layer 14 pattern-formed for each of the organic electroluminescent elements 11R (11), 11G, and 11B in the above-described manner is, for example, formed by an evaporation method and a transfer method by using a mask.

In the display device 10 of a first example constituted in this manner, the organic electroluminescent element (11) having the structure of the present invention which has been described by using FIG. 1 is used as the red light emitting element 11R. The red light emitting element 11R (11) has the high light emission efficiency while maintaining the red light emission color as described above. Thus, it is possible to perform a full color display with the high color representation characteristics by combination of the red light emitting element 11R (11), and the green light emitting element 11G and the blue light emitting element 11B.

Moreover, the luminance lifetime can be improved, and the effect of reducing the power consumption is brought in the display device 10 by use of the organic electroluminescent element (11) having the high light emission efficiency. Accordingly, the display device 10 can be suitably used as a flat panel display such as a wall-hung television, and a flat light emitting body, and application to a light source of a copy machine, a printer, and the like, a light source of a liquid crystal display, an instrument, and the like, a display board, a marker light, and the like is possible.

Moreover, in the above-described example, although the example in which the present invention is applied to the active-matrix type display device has been described, the present invention is applicable to a passive-matrix type display device, and it is possible to obtain the same effects in this case.

In addition, in each of the organic electroluminescent elements 11R (11), 11G, and 11B, layers other than the light emitting layer 14c may be used in common. Moreover, in the green light emitting element 11G and the blue light emitting element 11B, the electron transport layers 14d constituted of different materials may be provided to be suitable for the light emitting layers 14c-G, and 14c-B, respectively.

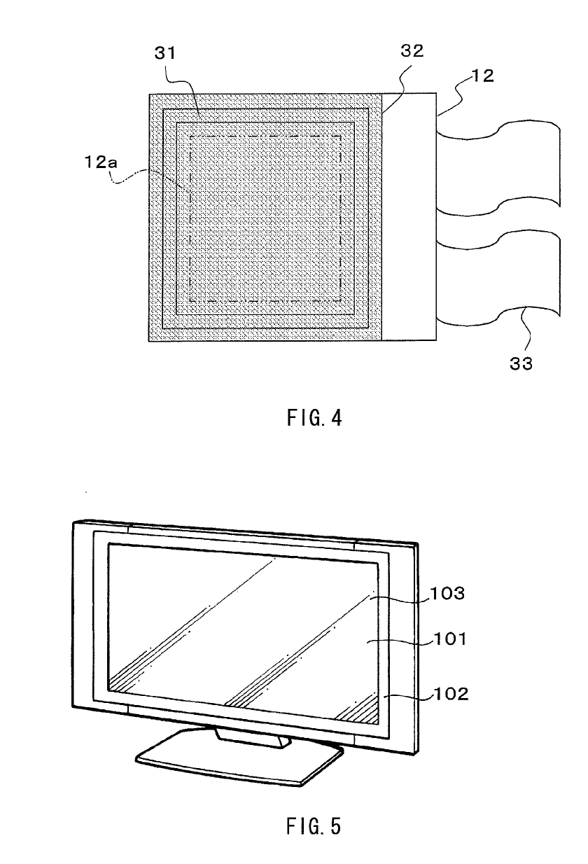

The above-described display device according to the present invention include a display device having a module shape of a sealed structure, as illustrated in FIG. 4. For example, a display module in which a sealing section 31 is provided to surround the display region 12a as being a pixel array section, and the display region 12a is bonded to a facing section (a sealing substrate 32) of transparent glass or the like by the sealing section 31 as an adhesive corresponds to the example. A color filter, a protective film, a light shielding film, and the like may be provided in the transparent sealing substrate 32. In addition, a flexible print board 33 inputting/outputting a signal and the like from outside to the display region 12a (the pixel array section) may be provided in the substrate 12 as the display module in which the display region 12a is formed.

### APPLICATION EXAMPLES

Moreover, the above-described display device according to the present invention is applicable to display devices in electronic devices in various fields for displaying a picture signal input to the electronic devices or a picture signal generated inside the electronic devices as an image or a picture, such as various electronic devices illustrated in FIGS. 5 to 9, for example, a digital camera, a notebook personal computer, a portable terminal device such as a portable phone, and a video camera. Hereinafter, examples of the electronic device to which the present invention is applied will be described.

FIG. 5 is a perspective view of a television device to which the present invention is applied. The television device includes a video display screen section 101 constituted of a front panel 102, a filter glass 103, and the like. The display device according to the present invention is used for the video display screen section 101.

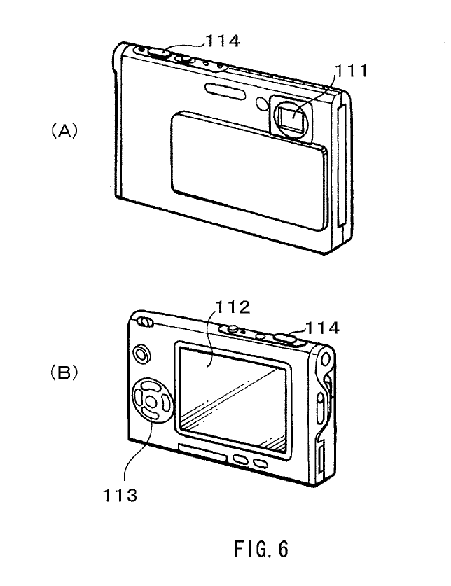

FIG. 6 is a view illustrating a digital camera to which the present invention is applied, (A) is a perspective view as viewed from a front side, and (B) is a perspective view as viewed from a rear side. The digital camera includes a light emitting section for a flash 111, a display section 112, a menu switch 113, a shutter button 114, and the like. The display device according to the present invention is used as the display section 112.

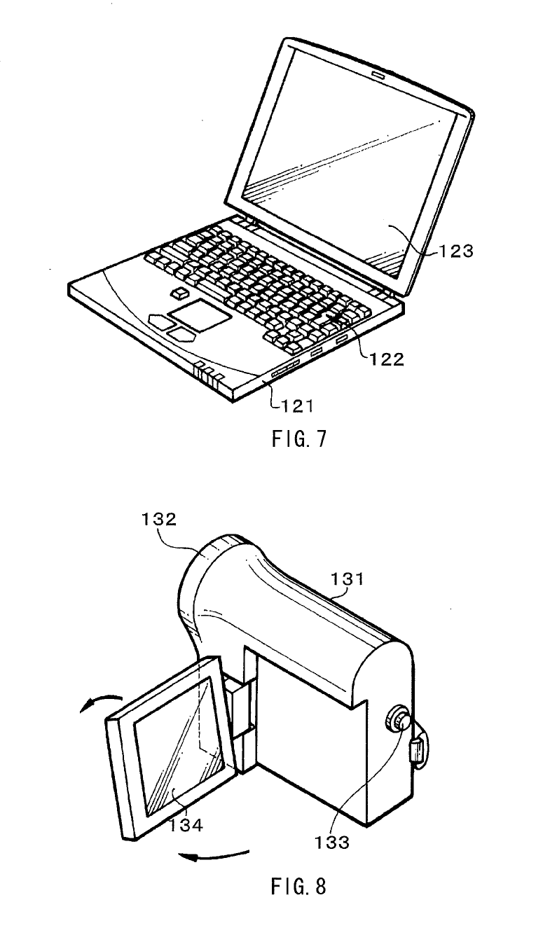

FIG. 7 is a perspective view illustrating a notebook personal computer to which the present invention is applied. The notebook personal computer includes a main body 121, a keyboard 122 for operation of inputting characters and the like, a display section 123 for displaying an image, and the like. The display device according to the present invention is used as the display section 123.

FIG. 8 is a perspective view illustrating a video camera to which the present invention is applied. The video camera includes a main body 131, a lens for capturing an object 132 provided on the front side face of the main body 131, a start/stop switch in capturing 133, a display section 134, and the like. The display device according to the present invention is used as the display section 134.

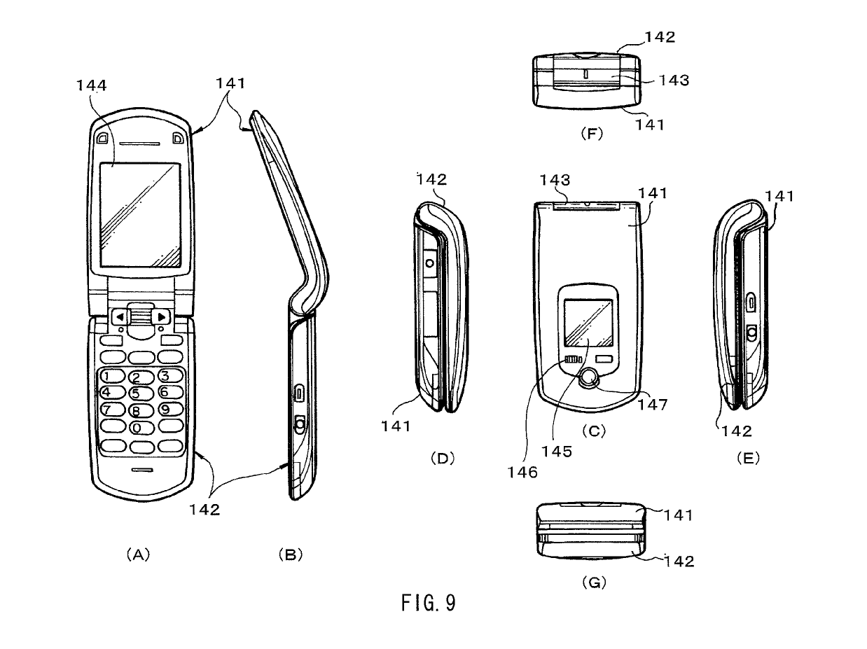

FIG. 9 is a view illustrating a portable terminal device, for example, a portable phone to which the present invention is applied, (A) is an elevation view in an unclosed state, (B) is a side view thereof, (C) is an elevation view in a closed state, (D) is a left side face view, (E) is a right side face view, (F) is a top view, and (G) is a bottom view. The portable phone includes an upper package 141 and a lower package 142, a joint section (here, a hinge section) 143, a display 144, a sub-display 145, a picture light 146, a camera 147, and the like. The display device according to the present invention is used as the display 144 and the sub-display 145.

### Examples

Manufacturing procedures of organic luminescent elements of specific examples of the present invention, and comparative examples will be described with reference to FIG. 1. Next, evaluation results of these will be described.

### Examples 1 to 8 and Comparative Examples 1 to 9

First, a cell for the organic electroluminescent element for the top emission in which an ITO transparent electrode of 12.5 nm was stacked on an Ag alloy (a reflecting layer) whose film thickness is 190 nm was fabricated as the anode 13 on the substrate 12 of a glass plate of 30 mm×30 mm.

Next, as the hole injection layer 14a of the organic layer 14, a film of m-MTDATA represented by the following structure formula (101) was formed by the vacuum evaporation method in a film thickness of 12 nm (at an evaporation rate of 0.2 to 0.4 nm/sec). However, m-MTDATA is 4,4′,4″-tris(phenyl-m-tolylamino) triphenylamine

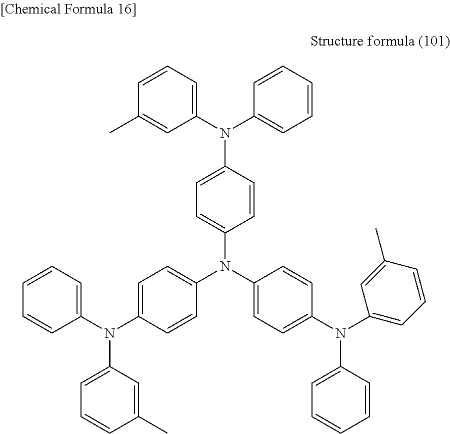

Next, as the hole transport layer 14b, a film of α-NPD represented by the following structure formula (102) was formed in a film thickness of 12 nm (at an evaporation rate of 0.2 to 0.4 nm/sec). However, α-NPD is N,N′-bis(1-naphthyl)-N,N′-diphenyl [1,1′-biphenyl]-4,4′-diamine

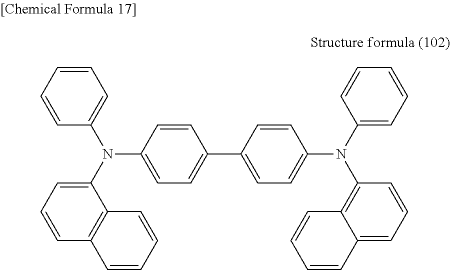

After that, for each of the examples 1 to 7 and the comparative examples 1 to 8, the light emitting layer 14c and the electron transport layer 14d were formed in this order by evaporation through use of materials selected as indicated in the following Table 2. In all the light emitting layers 14c, the film thickness was 30 nm, and the doping concentration of the guest materials was 1%. The film thickness of the electron transport layer 14d was 35 nm.

TABLE 2

| | Light emitting layer 14c | | Electron | Drive | Current | Color | |
|---|---|---|---|---|---|---|---|
| | Host | Guest | transport | current | efficiency | coordinate | Lifetime |
| | material | material | layer 14d | V | cd/A | (x, y) | hr |
| Example 1 | rubrene | structure | compound | 5.5 | 15 | (0.64, 0.34) | 1000 or more |
| | structure | formula | (1)-7 | | | | |
| Example 2 | formula | (105) | compound | 5.2 | 15.3 | (0.64, 0.34) | 1000 or more |
| | (103) | | (1)-6 | | | | |
| Example 3 | | | compound | 5.3 | 16 | (0.64, 0.34) | 1000 or more |
| | | | (1)-12 | | | | |
| (Comparative | | | structure | 7.3 | 6 | (0.54, 0.43) | 100 |
| example 1) | | | formula (110) | | | | |
| (Comparative | | | BCP | 6.3 | 5 | (0.60, 0.40) | 10 |
| example 2) | | | | | | | |
| (Comparative | | | BCP/structure | 9.2 | 8 | (0.62, 0.37) | 3 |
| example 3) | | | formula | | | | |
| | | | (110)(10/30) | | | | |
| (Comparative | ADN | | compound | 5.3 | 0.3 | (0.64, 0.34) | 0.3 |
| example 4) | structure | | (1)-1 | | | | |
| | formula | | | | | | |
| | (104) | | | | | | |
| Example 4 | rubrene | structure | compound | 5.8 | 8.3 | (0.60, 0.35) | 1000 or more |
| | structure | formula | (1)-12 | | | | |
| (Comparative | formula | (106) | structure | 9.2 | 3.6 | (0.54, 0.43) | 120 |
| example 5) | (103) | | formula (110) | | | | |
| Example 5 | | structure | compound | 5.4 | 13.6 | (0.67, 0.33) | 1000 or more |
| | | formula | (1)-12 | | | | |
| (Comparative | | (107) | structure | 9.3 | 4.3 | (0.54, 0.44) | 105 |
| example 6) | | | formula (110) | | | | |
| Example 6 | | structure | compound | 5.6 | 10 | (0.61, 0.36) | 1000 or more |
| | | formula | (1)-12 | | | | |
| (Comparative | | (108) | structure | 9.1 | 4.2 | (0.54, 0.43) | 55 |
| example 7) | | | formula (110) | | | | |
| Example 7 | | structure | compound | 5.4 | 6.4 | (0.65, 0.33) | 1000 or more |
| | | formula | (1)-12 | | | | |
| (Comparative | | (109) | structure | 9.6 | 2 | (0.52, 0.43) | 30 |
| example 8) | | | formula (110) | | | | |
| Example 8 | | structure | compound | 5.1 | 14 | (0.64, 0.34) | 1000 or more |
| | | formula | (1)-55 | | | | |
| (Comparative | | (105) | structure | 5.8 | 11 | (0.64, 0.34) | 200 |
| example 9) | | | formula (111) | | | | |

In each material indicated in Table 2, as the host material of the light emitting layer 14c, rubrene of the following structure formula (103) was used, and ADN of the structure formula (104) was used only in the comparative example 4.

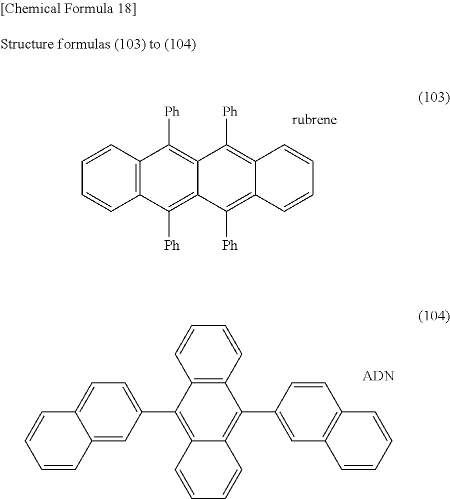

Moreover, as the guest material of the light emitting layer 14c, the perylene derivative of the following structure formula (105), the diketopyrrolopyrrole derivative of the structure formula (106), the pyrromethene complex of the structure formula (107), the pyrane derivative of the structure formula (108), or the styryl derivative of the structure formula (109) was used.

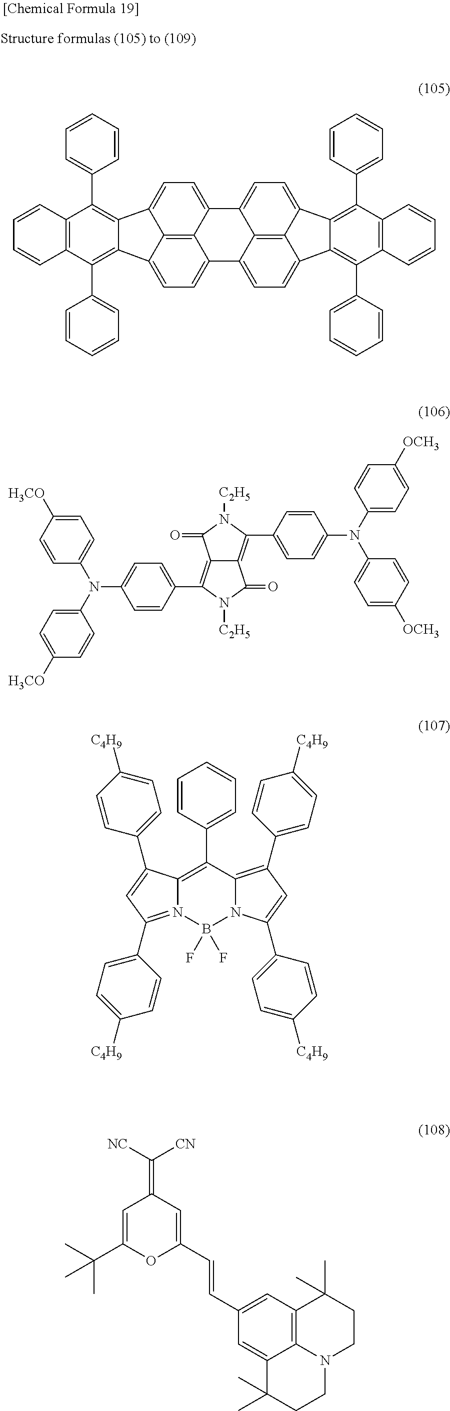

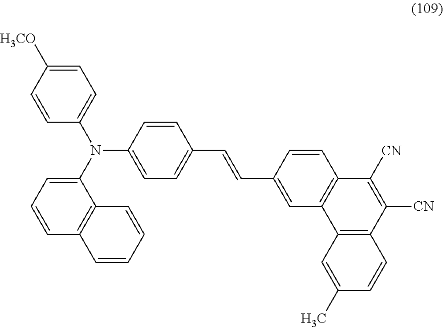

And, for the electron transport layer 14d, the compound (1)-1, the compound (1)-6, the compound (1)-7, the compound (1)-12, or the compound (1)-55 as being the benzimidazole derivative indicated in Table 1-1, Table 1-2, or Table 1-7, which is characteristic in the present invention, Alq3 of the following structure formula (110), the compound of the following structure formula (111), or BCP was used. In addition, in the comparative example 3, BCP (bathocuproine) and Alq3 of the structure formula (110) were used at a volume rate of 10:30. Moreover, the benzimidazole derivative of the structure formula (111) used in the comparative example 9 is a compound not included in the general formula (1).

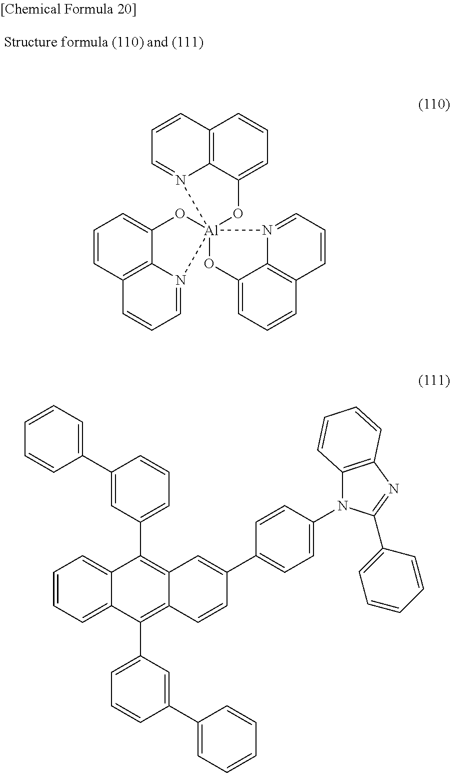

As described above, after the organic layer 14 in which the hole injection layer 14a, the hole transport layer 14b, the light emitting layer 14c, and the electron transport layer 14d were stacked in this order was formed, a film of LiF as the first layer 15a of the cathode 15 was formed in a film thickness of approximately 0.3 nm by the vacuum evaporation method (at an evaporation rate of 0.01 nm/sec.). Finally, an MgAg film as the second layer 15b of the cathode 15 was formed in a film thickness of 10 nm on the first layer 15a by the vacuum evaporation method.

<Evaluation Results>

In each of the organic electroluminescent elements fabricated in the examples 1 to 8 and the comparative examples 1 to 9, the drive voltage (V), the current efficiency (cd/A), and the color coordinate (x,y) were measured at the time of drive at a current density of 10 mA/cm2. Moreover, in the case where the initial luminance when a constant current drive was performed at 50° C. with a load of 100 mA/cm2 at duty 25% was set to 1, the time until when the luminance changed to 0.9 was measured as lifetime (hr). This result was shown in Table 2 in addition.

As shown in Table 2, it was confirmed that the drive voltage of any of the organic electroluminescent elements of the examples 1 to 8 in which the present invention was applied, the rubrene was used as the host material of the light emitting layer 14c, and the electron transport layer 14d of the benzimidazole derivative represented by the general formula (1) was provided was suppressed lower than the drive voltage of the organic electroluminescent elements of the comparative examples in which the present invention was not applied, and improvement was realized such that the current efficiency was approximately twice higher, and the lifetime was approximately ten times longer or more.

Moreover, in the examples 1 to 8, it was confirmed that the red light emission with high purity, as being the light emission from the light emitting guest material, could be obtained.

Meanwhile, in the organic electroluminescent elements of the comparative examples 1 to 3, and 5 to 9, because the electron supply to the light emission layer was insufficient, the drive voltage was increased, and the electron light emitting region was expanded to the electron transport layer, thereby generating deterioration of the light emission color and short lifetime. Moreover, in the organic electroluminescent element of the comparative example 4, the energy transfer from the host material to the light emitting guest material was unlikely to be generated, and the sufficient light emission efficiency was not obtained.

Moreover, it was possible for any of the organic electroluminescent elements of the examples to obtain the red light emission with the high purity, and this indicates that the full color display with the high color reproductively is possible by constituting a pixel of a combination of the organic electroluminescent element, and the green light emitting element and the blue light emitting element.

1. An organic electroluminescent element comprising:
an anode;
a cathode;
a light emitting layer containing a guest material having red light emission characteristics and a host material of a polycyclic aromatic hydrocarbon compound with a mother skeleton having 4 to 7 ring members, and held between the anode and the cathode; and
an electron transport layer containing a benzimidazole derivative represented by the following general formula (1), and held between the light emitting layer and the cathode in a state of being adjacent to the light emitting layer. 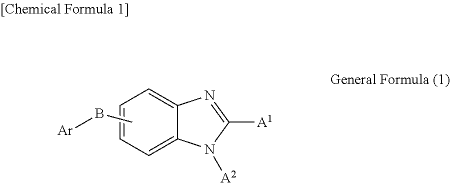
[In the general formula (1), A¹ and A² each independently represent a hydrogen atom, a substituted or unsubstituted aryl group having 60 or less carbon atoms, a substituted or unsubstituted heterocyclic group, a substituted or unsubstituted alkyl group having 1 to 20 carbon atoms, or an alkoxy group having 1 to 20 carbon atoms, B represents a paraphenylene group, and Ar represents an anthracene ring bonded to the paraphenylene group at a 2-position and a 6-position.]

2. The organic electroluminescent element according to claim 1, wherein the paraphenylene group represented by B in the general formula (1) is bonded to a benzimidazole ring at a 5-position.

3. The organic electroluminescent element according to claim 1, wherein the mother skeleton of the polycyclic aromatic hydrocarbon compound constituting the host material of the light emitting layer is selected from pyrene, benzopyrene, chrysene, naphthacene, benzonaphthacene, dibenzonaphthacene, perylene, and coronene.

4. The organic electroluminescent element according to claim 1, wherein the compound represented by the following general formula (2) is used as the host material of the light emitting layer. 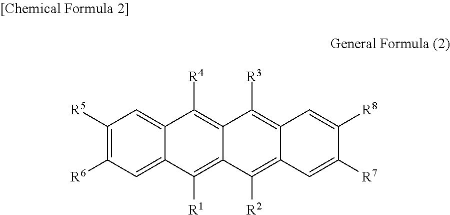
In the general formula (2), R¹ to R⁸ each independently represent hydrogen, halogen, a hydroxyl group, a substituted or unsubstituted carbonyl group having 20 or less carbon atoms, a substituted or unsubstituted carbonyl ester group having 20 or less carbon atoms, a substituted or unsubstituted alkyl group having 20 or less carbon atoms, a substituted or unsubstituted alkenyl group having 20 or less carbon atoms, a substituted or unsubstituted alkoxyl group having 20 or less carbon atoms, a cyano group, a nitro group, a substituted or unsubstituted silyl group having 30 or less carbon atoms, a substituted or unsubstituted aryl group having 30 or less carbon atoms, a substituted or unsubstituted heterocyclic group having 30 or less carbon atoms, or a substituted or unsubstituted amino group having 30 or less carbon atoms.

5. The organic electroluminescent element according to claim 1, wherein the electron transport layer is constituted of at least one kind of the benzimidazole derivative represented by the general formula (1).

6. The organic electroluminescent element according to claim 1, wherein the electron transport layer has a stacked structure.

7. The organic electroluminescent element according to claim 1, wherein the electron transport layer includes a layer formed by co-evaporating a plurality of kinds of the benzimidazole derivatives.

8. The organic electroluminescent element according to claim 1, wherein a perylene derivative, a diketopyrrolopyrrole derivative, a pyrromethene complex, a pyrane derivative, or a styryl derivative is used as the guest material having the red light emission characteristics contained in the light emitting layer.

9. A display device including an organic electroluminescent element comprising:
an anode;
a cathode;
a light emitting layer containing a guest material having red light emission characteristics and a host material of a polycyclic aromatic hydrocarbon compound with a mother skeleton having 4 to 7 ring members, and held between the anode and the cathode; and
an electron transport layer containing a benzimidazole derivative represented by the following general formula (1), and held between the light emitting layer and the cathode in a state of being adjacent to the light emitting layer. 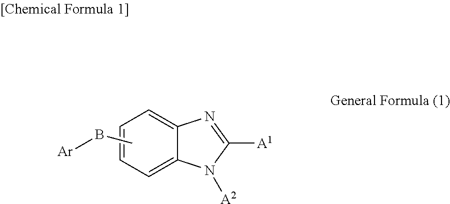
[In the general formula (1), A¹ and A² each independently represent a hydrogen atom, a substituted or unsubstituted aryl group having 60 or less carbon atoms, a substituted or unsubstituted heterocyclic group, a substituted or unsubstituted alkyl group having 1 to 20 carbon atoms, or an alkoxy group having 1 to 20 carbon atoms, B represents a paraphenylene group, and Ar represents an anthracene ring bonded to the paraphenylene group at a 2-position and a 6-position.]

10. The display device according to claim 9, wherein the organic electroluminescent element is provided as a red light emitting element in a part of pixels among a plurality of pixels.

11. The display device according to claim 10, wherein the red light emitting element, and a blue light emitting organic electroluminescent element and a green light emitting organic electroluminescent element are provided on the substrate.
